(19) United States
(12) Patent Application Publication
(10) Pub. No.: US 2024/0268141 A1
(43) Pub. Date: Aug. 8, 2024

(54) ORGANIC LIGHT EMITTING DIODE AND ORGANIC LIGHT EMITTING DEVICE

(71) Applicant: LG Display Co., Ltd., Seoul (KR)

(72) Inventors: Eun-Jung PARK, Paju-si (KR); Byung-Soo KIM, Paju-si (KR); Byung-Geol KIM, Paju-si (KR); Seung-Hyun KIM, Paju-si (KR); Ju-Hyuk KWON, Paju-si (KR); Jang-Dae YOUN, Paju-si (KR); Yu-Jeong LEE, Paju-si (KR); Min-Hyeong HWANG, Paju-si (KR); Do-Kyun KWON, Paju-si (KR); Hyun-Jin CHO, Paju-si (KR)

(73) Assignee: LG Display Co., Ltd., Seoul (KR)

(21) Appl. No.: 18/243,462

(22) Filed: Sep. 7, 2023

(30) Foreign Application Priority Data
Jan. 20, 2023 (KR) 10-2023-0008942

(51) Int. Cl. H10K 50/13; H10K 85/40; H10K 85/60

(52) U.S. Cl. CPC H10K 50/13; H10K 85/40; H10K 85/622; H10K 85/633; H10K 85/6572; H10K 2101/30

(57) ABSTRACT

An organic light emitting diode (OLED) and an organic light emitting device (e.g., a display device or a lighting device) comprising the OLED are described. An emissive layer includes a red emitting material layer, a yellow-green emitting material layer and a green emitting material layer disposed sequentially between two electrodes, where each of the emitting material layers has controlled thickness and includes at least one host with controlled energy level. The OLED and the organic light emitting device have improved pure color luminous efficiency and color gamut, as well as luminous efficiency and luminous lifespan.

### CROSS-REFERENCE TO RELATED APPLICATIONS

This application claims priority, under 35 U.S.C. § 119(a), to Korean Patent Application No. 10-2023-0008942, filed in the Republic of Korea on Jan. 20, 2023, the entire contents of which are hereby expressly incorporated by reference into the present application.

### BACKGROUND

### Technical Field

The present disclosure relates to an organic light emitting diode (OLED), preferably an (OLED) that has beneficial color gamut and white color temperature, as well as improved luminous efficiency and/or luminous lifespan. Further, the present disclosure also relates to an organic light emitting device (e.g., a display device or a lighting device) including the OLED.

### Description of the Related Art

A flat panel display device including an OLED has certain advantages over a liquid crystal display device (LCD). For instance, the OLED can be formed as a thin organic film less than 2000 Å and the electrode configurations can implement unidirectional or bidirectional images. Also, the OLED can be formed on a flexible transparent substrate such as a plastic substrate so that a flexible or a foldable display device can easily be manufactured using the OLED. In addition, the OLED can be driven at a lower voltage, and the OLED has higher color purity compared to the LCD.

However, there remains a need to develop OLEDs and devices thereof that have improved luminous efficiency and luminous lifespan. Since fluorescent materials use only singlet excitons in the luminous process, there is an issue with low luminous efficiency. Meanwhile, phosphorescent materials can show high luminous efficiency since they use triplet exciton as well as singlet excitons in the luminous process. But, examples of such phosphorescent material include metal complexes, which have a luminous lifespan that may be too short for commercial use. As such, there remains a need to develop an OLED with sufficient luminous efficiency, luminous lifespan and color purity.

### SUMMARY OF THE DISCLOSURE

Embodiments of the present disclosure are directed to an organic light emitting diode and an organic light emitting device thereof that address one or more of the limitations and disadvantages of the related art.

An aspect of the present disclosure relates to an OLED having beneficial color temperature of white color light and color gamut, as well as an organic light emitting device including the diode.

Another aspect of the present disclosure is to provide an organic light emitting diode that has improved luminous efficiency and luminous lifespan by distributing emission area uniformly in an emitting material layer, as well as an organic light emitting device including the diode.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims thereof, as well as the appended drawings.

As embodied and broadly described herein, in one aspect, the present disclosure provides an organic light emitting diode that comprises a first electrode; a second electrode facing the first electrode; and an emissive layer disposed between the first and second electrode, and comprising at least one emitting part. The at least one emitting part comprises a red emitting material layer comprises a first red host; a yellow-green emitting material layer disposed between the red emitting material layer and the second electrode, and comprising a first yellow-green host; and a green emitting material layer disposed between the yellow-green emitting material layer and the second electrode, and comprising a first green host, and wherein the green emitting material layer has a thickness larger than a thickness of the yellow-green emitting material layer.

The thickness of the green emitting material layer can be larger than a thickness of the red emitting material layer, and optionally, the red emitting material layer can have the thickness larger than the thickness of the yellow-green emitting material layer.

In certain aspects, the red emitting material layer can have the thickness in a range between about 100 Å and about 300 Å, the yellow-green emitting material layer can have the thickness in a range between about 50 Å and about 200 Å, and the green emitting material layer can have the thickness in a range between about 100 Å and about 400 Å, but is not limited thereto. In another aspect, the red emitting material layer has a thickness between about 125 Å and about 175 Å, the yellow-green emitting material layer has a thickness between about 90 Å and about 150 Å, and the green emitting material layer has a thickness between about 150 Å and about 250 Å. In certain aspects, the red emitting material layer can have the thickness in a range between about 100 Å and about 200 Å, about 120 Å and about 180 Å, about 130 Å and about 170 Å, about 140 Å and about 160 Å, about 130 Å, about 150 Å, or about 300 Å. In certain aspects, the yellow-green emitting material layer can have the thickness in a range between about 85 Å and about 150 Å, about 90 Å and about 120 Å, about 100 Å and about 150 Å, about 100 Å, about 140 Å, or about 180 Å. In certain aspects, the green emitting material layer can have the thickness in a range between about 100 Å and about 300 Å, about 150 Å and about 300 Å, about 200 Å and about 250 Å, about 150 Å, about 190 Å, about 250 Å, or about 300 Å.

The first green host can have a highest occupied molecular orbital (HOMO) energy level lower than a HOMO energy level of the first red host.

In certain aspects, the first red host is a compound according to Chemical Formula 1 or Chemical Formula 2, wherein the first yellow-green host and the first green host are each independently a compound according to Chemical Formula 9, or Chemical Formula 10, as described below.

The red emitting material layer can further comprise a second red host, the second red host can have an electron mobility larger than an electron mobility of the first red host, and a content of the second red host can be greater than a content of the first red host in the red emitting material layer.

Also, in certain aspects, the red emitting material layer further comprises a second red host selected from a compound according to Chemical Formula 3, Chemical Formula 4, Chemical Formula 5 or Chemical Formula 6, as described below.

In one embodiment, the red emitting material layer can further comprise a second red host, the second red host can have an electron mobility larger than an electron mobility of the first red host, and the second red host can have a lowest unoccupied molecular orbital (LUMO) energy level in a range between about −2.6 eV and about −3.2 eV.

The green emitting material layer can further comprise a second green host, the second green host can have an electron mobility larger than an electron mobility of the first green host, and a content of the first green host can be greater than a content of the second green host in the green emitting material layer.

In another embodiment, the green emitting material layer can further comprise a second green host, the second green host can have an electron mobility larger than an electron mobility of the first green host, and the second green host can have a HOMO energy level in a range between about −5.4 eV and about −5.9 eV.

In another embodiment, the red emitting material layer can further comprise a second red host, the yellow-green emitting material layer can further comprise a second yellow-green host and the green emitting material layer can further comprise a second green host, the second red host can have an electron mobility larger than an electron mobility of the first red host, the second yellow-green host can have an electron mobility larger than an electron mobility of the first yellow-green host and the second green host can have an electron mobility larger than an electron mobility of the first green host, and the second red host can have a LUMO energy level lower than a LUMO energy level of at least one of the second yellow-green host and the second green host.

In an embodiment, the emissive layer comprises a first emitting part; a second emitting part disposed between the first emitting part and the second electrode; and a first charge generation layer disposed between the first emitting part and the second emitting part, and one of the first emitting part and the second emitting part can comprise the red emitting material layer, the yellow-green emitting material layer and the green emitting material layer.

In one embodiment, the emissive layer can further comprise a third emitting part disposed between the second emitting part and the second electrode; and a second charge generation layer disposed between the second emitting part and the third emitting part.

In another aspect, the present disclosure provides an organic light emitting diode that comprises a first electrode; a second electrode facing the first electrode; and an emissive layer disposed between the first electrode and the second electrode. The emissive layer comprises a first emitting part; a second emitting part disposed between the first emitting part and the second electrode; and a first charge generation layer disposed between the first emitting part and the second emitting part. One of the first emitting part and the second emitting part comprises a first blue emitting material layer, and wherein another of the first emitting part and the second emitting part comprises a red emitting material layer comprising a first red host; a yellow-green emitting material layer disposed between the red emitting material layer and the second electrode, and comprising a first yellow-green host; and a green emitting material layer disposed between the yellow-green emitting material layer and the second electrode, and comprising a first green host, and wherein each of the red emitting material layer and the green emitting material layer has a thickness larger than a thickness of the yellow-green emitting material layer.

For example, the first emitting part can comprise the first blue emitting material layer and the second emitting part can comprise the red emitting material layer, the yellow-green emitting material layer and the green emitting material layer.

In yet another aspect, the present disclosure provides an organic light emitting device, for example, an organic light emitting display device or an organic light emitting illumination device that comprises a substrate and the organic light emitting diode over the substrate.

In one or more embodiments, each of the red emitting material layer, the yellow-green emitting material layer and the green emitting material layer can have a controlled thickness and comprises a host whose energy level and/or a content are controlled.

The emission intensity in ranges of the red and/or green wavelength can be higher or at least about 0.8 times based upon the emission intensity in a range of the yellow-green wavelength. As the intensity of the pure color such as red color and/or green color increases, the color temperature of the white light can be improved and the color gamut can be enhanced.

The amount or contents of the host with relatively higher electron mobility is relatively large in the emitting material layer disposed adjacently to the hole transport layer and the amount or contents of the host with relatively higher hole mobility is relatively large in the emitting material layer disposed adjacently to the electron transport layer, so that emission area of exciton recombination zone can be distributed uniformly and extended to the entire emitting material layer. As excitons are not lost outside of the emitting material layer, the amount of non-emitting excitons can be minimized. The excitons are not quenched as non-emission by triplet-triplet annihilation (TTA) and/or triplet-polaron annihilation (TPA).

As the excitons are not biased toward a particular area in the emitting material layer and the exciton recombination zone is distributed uniformly in the entire emitting material layer, the degradation of the materials caused by excessive excitons can be prevented and the degradation of the luminous material caused by the non-emitting excitons can be minimized.

As the exciton quenching within the emitting material layer and outside of the emitting material layer minimizes, the driving voltage of the OLED cannot be raised with realizing low power consumption, and the red and green luminous lifespan can be secured stably.

It is possible to operate an OLED and an organic light emitting device thereof, which can have beneficial luminous lifespan of the red and green lights while maintaining stable red emission, yellow-green emission and green emission by adopting the structure of the emitting material layer of the present disclosure.

It is to be understood that both the foregoing general description and the following detailed description are merely by way of example and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device according to one or more embodiments of the present disclosure.

FIG. 2 illustrates a cross-sectional view of an organic light emitting display device as an example of an organic light emitting device in accordance with one or more embodiments of the present disclosure.

FIG. 3 illustrates a cross-sectional view of an organic light emitting diode having a tandem structure with two emitting parts in accordance with one or more embodiments of the present disclosure.

FIG. 4 illustrates a schematic diagram showing thicknesses and energy levels of emitting material layers in a conventional organic light emitting diode.

FIG. 5 illustrates a schematic diagram showing thicknesses and energy levels of emitting material layer in accordance with one or more embodiments of the present disclosure.

FIG. 6 illustrates a schematic diagram showing energy levels of host in emitting material layer in accordance with one or more embodiments of the present disclosure.

FIG. 7 illustrates a cross-sectional view of an organic light emitting diode having a tandem structure with three emitting parts in accordance with one or more embodiments of the present disclosure.

FIGS. 8 and 9 illustrate examples of measurement results showing electroluminescence (EL) spectra of an OLED fabricated in Examples in the following and Comparative Example.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts. In the following description, when a detailed description of well-known functions or configurations related to this document is determined to unnecessarily cloud a gist of the inventive concept, the detailed description thereof will be or can be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations are selected only for convenience of writing the specification and can be thus different from those used in actual products. Further, all the components of each organic light emitting diode (OLED) and each organic light emitting device (e.g., display device, illumination device, etc.) using the OLED according to all embodiments of the present disclosure are operatively coupled and configured.

The present disclosure relates to an organic light emitting diode and/or an organic light emitting device where a red emitting material layer, a yellow-green emitting material layer and a green emitting material layer each of which has a controlled thickness and includes at least one host with controlled energy levels and the contents so that color temperature of the white light, color gamut, luminous efficiency and/or luminous lifespan can be maximized.

As an example, in one or more embodiments of the present disclosure, the emissive layer of the organic light emitting diode or the device can be applied into an organic light emitting diode where multiple emitting parts are stacked to form a tandem-structure. The organic light emitting diode can be applied to an organic light emitting device such as an organic light emitting display device or an organic light emitting illumination device.

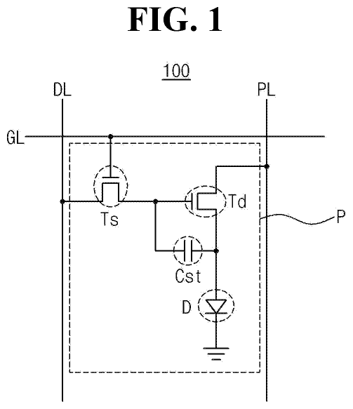

FIG. 1 illustrates a schematic circuit diagram of an organic light emitting display device in accordance with one or more embodiments of the present disclosure.

As illustrated in FIG. 1, a gate line GL, a data line DL and a power line PL, each of which crosses each other to define a pixel region P, are provided in an organic light emitting display device 100. A switching thin film transistor Ts, a driving thin film transistor Td, a storage capacitor Cst and an organic light emitting diode D are disposed within the pixel region P. The pixel region P can include a red (R) pixel region, a green (G) pixel region and a blue (B) pixel region. The organic light emitting display device 100 includes a plurality of such pixel regions P which can be arranged in a matrix configuration or other configurations. Further, each pixel region P can include one or more subpixels. However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

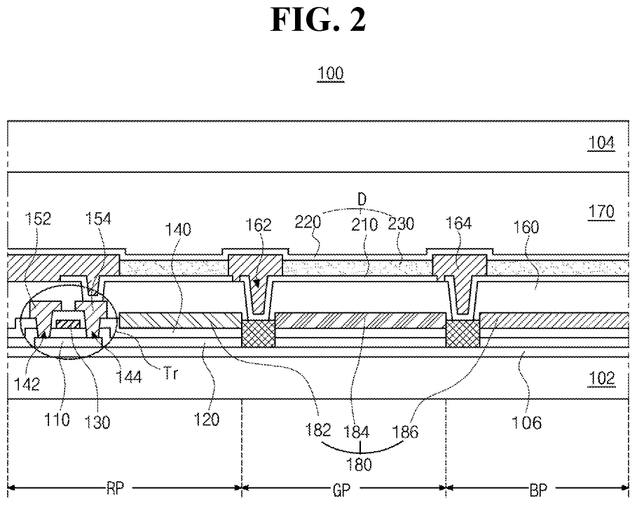

The driving thin film transistor Td is turned on by the data signal applied to a gate electrode 130 (FIG. 2) so that a current proportional to the data signal is supplied from the power line PL to the organic light emitting diode D through the driving thin film transistor Td. Then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an embodiment of the present disclosure. The pixel circuit configuration of FIG. 1 can be used in the display device of FIG. 2 or other figures of the present application.

As illustrated in FIG. 2, the organic light emitting display device 100 includes a first substrate 102 that defines each of a red pixel region RP, a green pixel region GP and a blue pixel region BP, a second substrate 104 facing the first substrate 102, a thin film transistor Tr on the first substrate 102, an organic light emitting diode (OLED) D disposed between the first and second substrates 102 and 104 and emitting white (W) light and a color filter layer 180 disposed between the OLED D and the first substrate 102. The organic light emitting display device 100 can include a plurality of such pixel regions arranged in a matrix configuration or other suitable configurations.

Each of the first substrate 102 and the second substrate 104 can include, but is not limited to, glass, thin flexible material and/or polymer plastics. For example, the flexible material in the first substrate 102 and/or the second substrate 104 can be selected from, but is not limited to, polyimide (PI), polyethersulfone (PES), polyethylenenaphthalate (PEN), polyethylene terephthalate (PET), polycarbonate (PC) and/or combinations thereof. The first substrate 102, on which the thin film transistor Tr and the organic light emitting diode D are arranged, forms an array substrate. In certain embodiments, the second substrate 104 can be omitted.

A buffer layer 106 can be disposed on the first substrate 102. The thin film transistor Tr can be disposed on the buffer layer 106 correspondingly to each of the red pixel region RP, the green pixel region GP and the blue pixel region BP. In certain embodiments, the buffer layer 106 can be omitted.

A semiconductor layer 110 is disposed on the buffer layer 106. In one embodiment, the semiconductor layer 110 can include, but is not limited to, oxide semiconductor materials. In this case, a light-shield pattern can be disposed under the semiconductor layer 110, and the light-shield pattern can prevent light from being incident toward the semiconductor layer 110, thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the substrate 102 as shown in FIG. 2, the gate insulating layer 120 can be patterned identically as the gate electrode 130.

An interlayer insulating layer 140 including an insulating material is disposed on the gate electrode 130 and covers an entire surface of the substrate 102. The interlayer insulating layer 140 can include, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has a first semiconductor layer contact hole 142 and a second semiconductor layer contact holes 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon. Here, the designation of the source and drain electrodes 152 and 154 can be switched with each other depending on the type and configuration of a transistor.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr can further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the entire substrate 102. The passivation layer 160 has a flat top surface and a drain contact hole (or a contact hole) 162 that exposes or does not cover the drain electrode 154 of the thin film transistor Tr. While the drain contact hole 162 is disposed on the second semiconductor layer contact hole 144, it can be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 can be disposed in each pixel region RP, GP or BP. In one embodiment, the first electrode 210 can be an anode and include conductive material having relatively high work function value. For example, the first electrode 210 can include a transparent conductive oxide (TCO).

In one embodiment, when the organic light emitting display device 100 is a bottom-emission type, the first electrode 210 can have a single-layered structure of the TCO.

In addition, a bank layer 164 is disposed on the passivation layer 160 in order to cover edges of the first electrode 210. The bank layer 164 exposes or does not cover a center of the first electrode 210 corresponding to each pixel region RP, GP or BP. In certain embodiments, the bank layer 164 can be omitted.

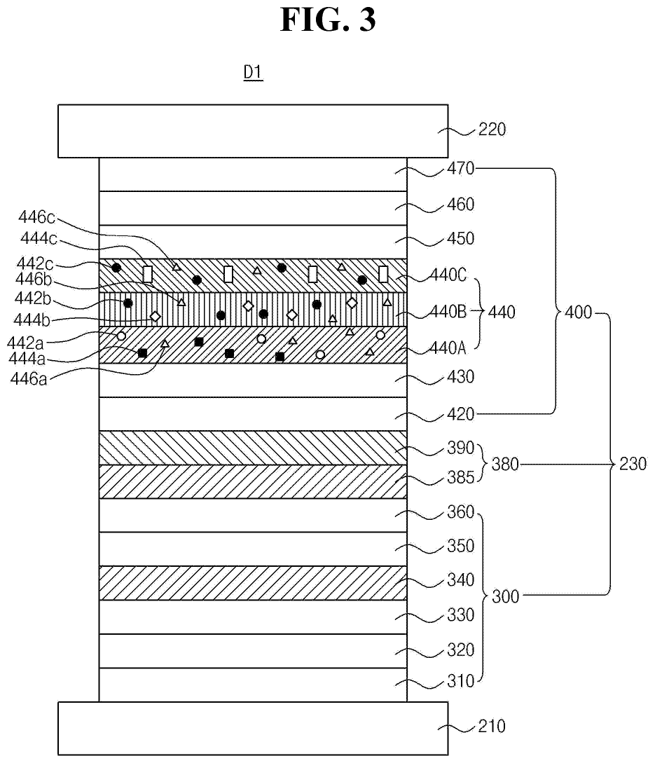

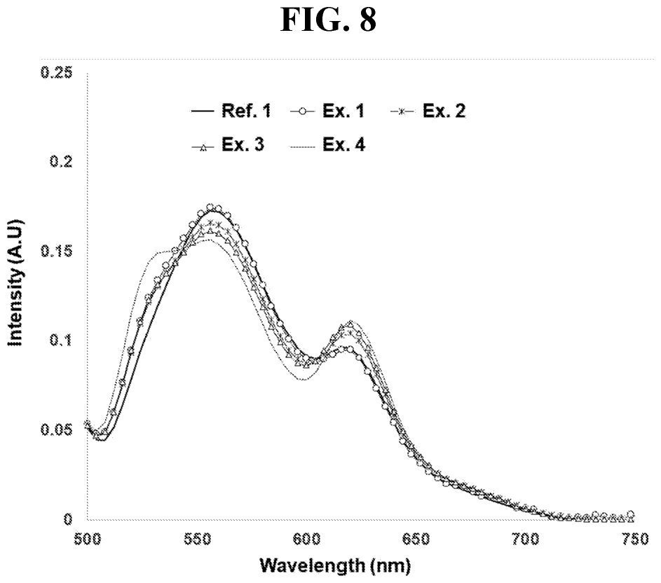

The emissive layer 230 is disposed on the first electrode 210. In one embodiment, the emissive layer 230 can have at least one emitting part. For example, as illustrated in FIGS. 3 and 7, the emissive layer 230 can include multiple emitting parts 300, 400, 400A and 500 and at least one charge generation layer 380 and 480. Each emitting part 300, 400, 400A or 500 can include only an emitting material layer (EML).

Alternatively, each of the emitting parts 300, 400, 400A and 500 in the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIGS. 3 and 7).

In one embodiment, the emissive layer 230 can have a single emitting part. Alternatively, the emissive layer 230 can have multiple emitting parts to form a tandem structure. For example, the emissive layer 230 can be applied to an organic light emitting diode having a single emissive layer disposed in each of the red pixel region, the green pixel region and the blue pixel region, respectively. Alternatively, the emissive layer 230 can be applied to an organic light emitting diode of a tandem structure stacked multiple emitting parts.

The emissive layer 230 can include a red emitting material layer, a yellow-green emitting material layer and a green emitting material layer each of which has a controlled thickness and includes a host with controlled contents and/or energy levels.

The second electrode 220 is disposed on the substrate 102 above which the emissive layer 230 is disposed. The second electrode 220 can be disposed on the entire display area. The second electrode 220 can include a conductive material with a relatively low or lower work function value compared to the first electrode 210, and can be a cathode providing electrons.

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film, an organic insulating film and a second inorganic insulating film. In certain embodiments, the encapsulation film 170 can be omitted.

A polarizing plate can be attached onto the encapsulation film 170 to reduce reflection of external light. For example, the polarizing plate can be a circular polarizing plate. When the organic light emitting display device 100 is a bottom-emission type, the polarizing plate can be disposed under the first substrate 102. Alternatively, when the organic light emitting display device 100 is a top-emission type, the polarizing plate can be disposed on the encapsulation film 170 or the second substrate 104. In addition, a cover window can be attached to the encapsulation film 170 or the polarizing plate in the organic light emitting display device 100 of the top-emission type. In this case, the first substrate 102, the second substrate 104 and the cover window can have a flexible property, thus the organic light emitting display device 100 can be a flexible display device.

The color filter layer 180 is disposed between the first substrate 102 and the OLED D, for example, the interlayer insulating layer 140 and the passivation layer 160. The color filter layer 180 can include a red color filter pattern 182, a green color filter pattern 184 and a blue color filter pattern 186 each of which is disposed correspondingly to the red pixel region RP, the green pixel region GP and the blue pixel region BP, respectively.

In FIG. 2, the light emitted from the OLED D is transmitted through the first electrode 210 and the color filter layer 180 is disposed under the OLED D. The organic light emitting display device 100 can be a bottom-emission type. Alternatively, the light emitted from the OLED D is transmitted through the second electrode 220 and the color filter layer 180 can be disposed on the OLED D when the organic light emitting display device 100 is a top-emission type. In this case, the color filter layer 180 can be attached to the OLED D by adhesive layer. Alternatively, the color filter layer 180 can be disposed directly on the OLED D. When the organic light emitting display device 100 is a top-emission type, a reflective electrode or a reflective layer can be further disposed under the first electrode 210. For example, the reflective electrode or the reflective layer can include silver (Ag) or aluminum-palladium-copper (APC) alloy.

In addition, a color conversion layer can be formed or disposed between the OLED D and the color filter layer 180. The color conversion layer can include a red color conversion layer, a green color conversion layer and a blue color conversion layer each of which is disposed correspondingly to each pixel region (RP, GP and BP), respectively, so as to convert the white (W) color light to each of a red, green and blue color lights, respectively. For example, the color conversion layer can include quantum dots so that the color purity of the organic light emitting display device 100 can be further improved. Alternatively, the organic light emitting display device 100 can comprise the color conversion layer instead of the color filter layer 180.

The OLED D is described in more detail. FIG. 3 illustrates a schematic cross-sectional view of an organic light emitting diode having two emitting parts in accordance with an embodiment of the present disclosure. For instance, FIG. 3 shows an example (OLED D1) of the OLED D in FIGS. 1 and 2.

As illustrated in FIG. 3, the organic light emitting diode (OLED) D1 in accordance with an embodiment includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 can be disposed in the red pixel region RP, the green pixel region GP and the blue pixel region BP.

The first electrode 210 can be an anode that provides holes into the emitting material layer (EML). The first electrode 210 can include a conductive material having a relatively high work function value, for example, a transparent conductive oxide (TCO). For example, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

The second electrode 220 can be a cathode that provides electrons into the EML. The second electrode 220 can include a conductive material having a relatively low work function value. For example, the second electrode 220 can include a highly reflective material, including but not limited to: aluminum (Al), magnesium (Mg), calcium (Ca), silver (Ag), alloy thereof and/or combinations thereof, e.g., such as aluminum-magnesium alloy (Al—Mg).

The emissive layer 230 can include a first emitting part 300 disposed between the first electrode 210 and the second electrode 220, a second emitting part 400 disposed between the first emitting part 300 and the second electrode 220, and a charge generation layer (CGL) 380 disposed between the first emitting part 300 and the second emitting part 400.

The first emitting part 300 includes a first emitting material layer (EML1) 340. The first emitting part 300 can include at least one of a first hole transport layer (HTL1) 320 disposed between the first electrode 210 and the EML1 340 and a first electron transport layer (ETL1) 360 disposed between the EML1 340 and the CGL 380. The first emitting part 300 can further include a hole injection layer (HIL) 310 disposed between the first electrode 210 and the HTL1 320. Alternatively, or additionally, the first emitting part 300 can further include a first electron blocking layer (EBL1) 330 disposed between the HTL1 320 and the EML1 340 and/or a first hole blocking layer (HBL1) 350 disposed between the EML1 340 and the ETL1 360.

The second emitting part 400 includes a second emitting material layer (EML2) 440. The second emitting part 400 can include at least one of a second hole transport layer (HTL2) 420 disposed between the CGL 380 and the EML2 440 and a second electron transport layer (ETL2) 460 disposed between the EML2 440 and the second electrode 220. The second emitting part 400 can further include an electron injection layer (EIL) 470 disposed between the ETL2 460 and the second electrode 220. Alternatively, or additionally, the second emitting part 400 can further include at least one of a second electron blocking layer (EBL2) 430 disposed between the HTL2 420 and the EML2 440 and a second hole blocking layer (HBL2) 450 disposed between the EML2 440 and the ETL2 460.

One of the EML1 340 and the EML2 440 emits blue color light and the other of the EML1 340 and the EML2 440 emits red, yellow-green and green color lights. Hereinafter, the OLED D1 where the EML1 340 emits blue color light and the EML2 440 emits red, yellow-green and green color lights will be described in detail.

The EML2 440 can include a red emitting material layer (first layer, R-EML) 440A, a yellow-green emitting material layer (second layer, YG-EML) 440B and a green emitting material layer (third layer, G-EML) 440C disposed sequentially between the CGL 380 and the second electrode 220, for example, HTL2 420 or the EBL2 430 and the ETL2 460 or the HBL 450.

The first layer 440A can include a first red host 442a and a red emitter (red dopant) 446a, and optionally, a second red host 444a. The second layer 440B can include a first yellow-green host 442b and a yellow-green emitter (yellow-green dopant) 446b, and optionally, a second yellow-green host 444b. The third layer 440C can include a first green host 442c and a green emitter (green dopant) 446c, and optionally, a second green host 444c.

In one embodiment, each of the first red host 442a, the first yellow-green host 442b and the first green host 442c can be independently a hole-type (H-type or P-type) host with relatively strong hole affinity properties. Each of the second red host 444a, the second yellow-green host 444b and the second green host 444c can be independently an electron type (E-type or N-type) host with relatively strong electron affinity properties. The luminous properties of the OLED D1 can be improved by controlling the thickness of the first to third layers 440A 440B and 440C and/or contents and energy levels of the hosts 442a, 444a, 442b, 444b, 442c and/or 444c.

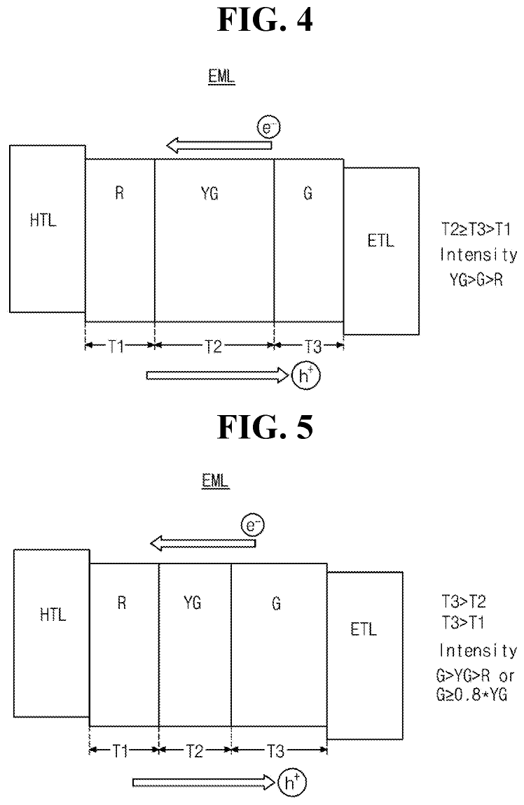

FIG. 4 illustrates a schematic diagram showing thicknesses and energy levels of emitting material layers in a conventional organic light emitting diode. As illustrated in FIGS. 3 and 4, the YG-EML 440B has a thickness T2 larger than a thickness T1 of the R-EML 440A or a thickness T3 of the G-EML 440C in the conventional EML2 440. Accordingly, the emission intensity in a yellow-green (YG) wavelength range is larger than the emission intensity in a green (G) wavelength range, and the emission intensity in the green (G) wavelength range is larger than the emission intensity in a red (R) wavelength range in the conventional EML2 440 where the three emitting material layers are located sequentially.

As used herein, the green (G) wavelength range can indicate a wavelength range between about 510 nm and about 540 nm, the yellow-green (YG) wavelength range can indicate a wavelength range between about 550 nm and about 580 nm, and the red (R) wavelength range can include a wavelength range between about 600 nm and about 650 nm.

For example, each of the intensities of the green (G) emission at 525 nm, the yellow-green (YG) emission at 556 nm and the red (R) emission at 600 nm with regard to the entire electroluminescence (EL) within the EML2 440 in the conventional organic light emitting diode in FIG. 4 can be 0.115, 0.164 and 0.0885, respectively, for example, about 0.7:1:0.55. As the yellow-green (YG) emission intensity is relatively strong compared to the emission intensity of the pure color light such as the red (R) light and the green (G) light, the pure color efficiency is lowered. Accordingly, the color gamut of the organic light emitting diode can be lowered and pure color luminance and luminance to the CMY driving can be reduced. In addition, there is a disadvantage of raising extremely the blue light efficiency to match the correlated color temperature (CCT) of the white color light of 10,000 K level.

With regard to driving a display panel, white light luminance of at least 180 nit (cd/m²) in white color tracking driving and white light luminance of about 150 nit in RGB driving can be possible based on identical power consumption. The maximum white light luminance is only about 150 nit in an organic light emitting device with the conventional organic light emitting diode, so that the performances and the color gamut of the conventional organic light emitting diode can be lowered.

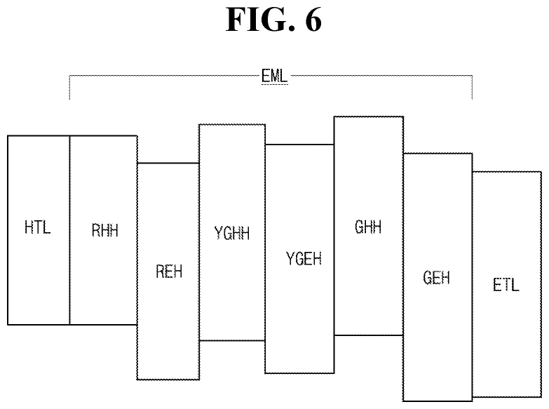

FIG. 5 illustrates a schematic diagram showing thicknesses and energy levels of emitting material layer in accordance with one embodiment of the present disclosure. As illustrated in FIGS. 3 and 5, the G-EML 440C can have a thickness T3 larger than a thickness T2 of the YG-EML 440B and a thickness T1 of the R-EML 440A of the EML2 440 in the OLED D1. Alternatively, or additionally, the thickness T1 of the R-EML 440A can be larger than the thickness T2 of the YG-EML 440B.

In one embodiment, the thickness T3 of the G-EML 440C can be about 1.2 times to about 10 times, for example, about 1.5, 2.0, 2.5, 3.0, 3.5, 4.0, 4.5, 5.0, 6.0, 7.0, 8.0, or 9.0 times larger than the thickness T2 of the YG-EML 440B. In another embodiment, the thickness T3 of the G-EML 440C can be about 1.3 times to about 4 times, for example, about 1.5 times to about 2 times, for example, about 1.6, 1.7, 1.8, or 1.9 times larger than the thickness T1 of the R-EML 440A. In another embodiment, the thickness T1 of the R-EML 440A can be about 0.8 times to about 3 times, for example, about 0.9 times to about 2.0 times, for example, about 1.2 times to about 1.5 times larger than the thickness T2 of the YG-EML 440B. As an example, the R-EML 440A can have the thickness T1 in a range between about 100 Å and about 180 Å, the YG-EML 440B can have the thickness T2 in a range between about 100 Å and about 150 Å, and the G-EML 440C can have the thickness T3 in a range between about 180 Å and about 300 Å, but is not limited thereto.

The emission intensity of the green (G) light emitted from the OLED D1 or the organic light emitting display device 100 among the light emitted from the EML2 440 can be larger than the emission intensity of the yellow-green (YG) light. Alternatively, the emission intensity of the green (G) light and/or the emission intensity of the red (R) light emitted from the EML2 440 can be at least 0.8 times compared to the emission intensity of the yellow-green (YG) light. The emission intensity of the red (R) light and/or the green (G) light in the EML2 440 are improved so that the color gamut, pure color luminance of the OLED D1 as well as the luminance of the final product can be improved.

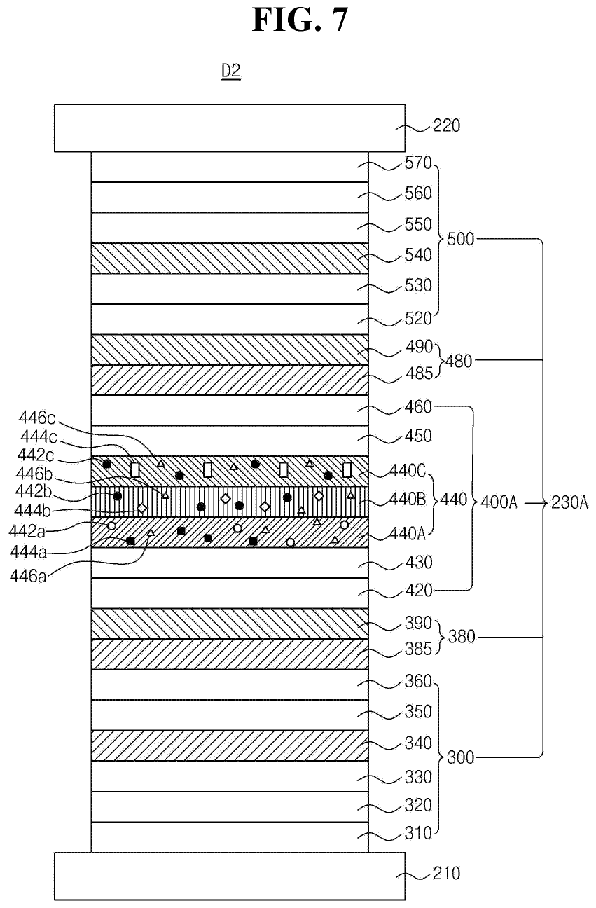

FIG. 6 illustrates a schematic diagram showing energy levels of host in emitting material layer in accordance with one embodiment of the present disclosure. With referring to FIGS. 3 and 6, the first green host (GHH) 442c can have a highest occupied molecular orbital (HOMO) energy level lower (deeper) than a HOMO energy level of the first red host (RHH) 442a. In another embodiment, the first yellow-green host (YGHH) 442b can have a HOMO energy level lower than the HOMO energy level of the first red host (RHH) 442a. Holes injected to the EML2 440 from the HTL2 420 can be transferred efficiently to the G-EML 440C from the R-EML 440A through the YG-EML 440B.

As an example, each of the first green host (GHH) 442c and/or the first yellow-green host (YGHH) 442b can have the HOMO energy level lower than the HOMO energy level of the first red host (RHH) 442a by about 0.1 eV to about 0.2 eV, for example, about 0.12 eV, 0.15 eV, or 0.18 eV. For example, the first red host (RHH) 442a can have the HOMO energy level in a range between about −5.3 eV and about −5.7 eV, and each the first green host (GHH) 442c and the first yellow-green host (YGHH) 442b can independently have the HOMO energy level in a range between about −5.4 eV and about −5.9 eV, respectively, but is not limited thereto.

In another embodiment, the second red host (REH) 444a can have a lowest unoccupied molecular orbital (LUMO) energy level lower that a LUMO energy level of the second yellow-green host (YGEH) 444b and/or the second green host (GEH) 444c. Electrons injected to the EML2 440 from the ETL2 460 can be transferred efficiently to the R-EML 440A from the G-EML 440C through the YG-EML 440B.

As an example, energy difference between the LUMO energy level of the second red host (REH) 444a and the LUMO energy level of the second green host (GEH) 440c can be within about 0.2 eV, for example, about 0.1 eV. In another embodiment, the second red host (REH) 444a can have the LUMO energy level lower than the LUMO energy level of the second yellow-green host (YGEH) 444b by about 0.2 eV to about 0.7 eV, for example, about 0.3 eV to about 0.6 eV, or about 0.4 eV to about 0.5 eV. For example, the second red host (REH) 444a can have the LUMO energy level in a range between about −2.6 eV and about −3.2 eV, for example, about −2.7 eV and about −3.1 eV, the second yellow-green host (YGEH) 444b can have the LUMO energy level in a range between about −2.3 eV and about −2.7 eV, for example, about −2.4 eV and about −2.6 eV, and the second green host (GEH) 444c can have the LUMO energy level in a range between about −2.6 eV and about −3.1 eV, for example, about −2.7 eV and about −3.0 eV, but is not limited thereto.

In another embodiment, the contents or the amount of the second red host (REH) 444a of the E-type host in the R-EML 440A disposed adjacently to the HTL2 420 can be greater than the contents or the amount of the first red host (RHH) 442a of the H-type host. As an example, the second red host (REH) 444a and the first red host (RHH) 442a in the R-EML 440A can be mixed, but is not limited to, with a weight ratio of about 6:4 to about 9:1, for example, about 6:4 to about 8:2.

In another embodiment, the contents or the amount of the first green host (GHH) 442c of the H-type host in the G-EML 440C disposed adjacently to the ETL2 460 can be greater than the contents or the amount of the second green host (GEH) 444c of the E-type host. As an example, the first green host (GHH) 442c and the second green host (GEH) 444c in the G-EML 440C can be mixed, but is not limited to, with a weight ratio of about 6:4 to about 9:1, for example, about 6:4 to about 8:2.

Holes are injected to the EML 440 from the HTL2 420, and then can be transferred efficiently to the G-EML 440C where the contents of the first green host (GHH) 442c of the H-type host with relatively beneficial hole mobility property is larger than the contents of the second green host (GEH) 444c of the E-type host from the R-EML 440A disposed adjacently to the HTL2 420. In addition, electrons are injected to the EML 440 from the ETL2 460, and then can be transferred efficiently to the R-EML 440A where the contents of the second red host (REH) 444a of the E-type host with relatively beneficial electron mobility property is larger than the contents of the first red host (RHH) 442a of the H-type host from the G-EML 440C disposed adjacently to the ETL2 460. Therefore, exciton recombination zone is distributed uniformly and extended to the entire area of the EML2 440.

In another embodiment, the first yellow-green host (YGHH) 442b and the second yellow-green host (YGEH) 444b in the YG-EML 440B can be mixed, but is not limited to, a weight ratio of 3:1 to 1:3, for example, about 7:3 to about 3:7 or about 6:4 to about 4:6.

As the exciton recombination zone is generated uniformly in the entire area of the R-EML 440A, the YG-EML 440B and the G-EML 440C within the EML2 440, the degradations of the luminous materials caused by excessive excitons in the EML2 440 can be minimized. In addition, as the holes and electrons injected into the EML2 440 can generate excitons within the EML2 440 to emit, the amount of non-radiative quenching excitons can be minimized.

The interactions among the non-radiative quenching excitons and the luminous materials within the EML2 440 and/or the charge transporting materials in the HTL2 420 and/or the ETL2 460 can be prevented. The degradations of the luminous materials and/or the charge transporting materials caused by the interactions with the non-radiative quenching excitons can be minimized, and therefore, the luminous properties, for example, the luminous lifespan of the OLED D1 can be improved greatly.

Each of the first red host (RHH) 442a, the first yellow-green host (YGHH) 442b and the first green host (GHH) 442c of the H-type host can independently include, but is not limited to, at least one of an aromatic/hetero aromatic amino-containing compound substituted with at least one aromatic and/or hetero aromatic group, a carbazole-containing compound and a spirofluorene-containing compound.

Each of the second red host (REH) 444a, the second yellow-green host (YGEH) 444b and the second green host (GEH) 444c of the E-type host can independently include, but is not limited to, at least one of an azine—(e.g., triazine-, pyridine- or pyrimidine-) containing compound, a quinazoline-containing compound and a benzimidazole-containing compound.

In one embodiment, the first red host (RHH) 442a can include an aromatic/hetero aromatic amino-containing organic compound having the following structure of Chemical Formula 1:

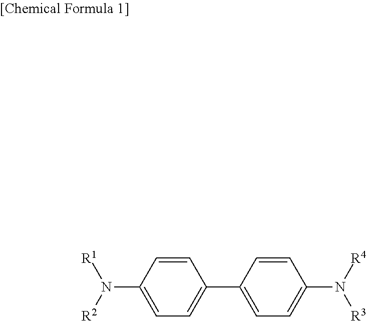

wherein, in Chemical Formula 1,
each of R¹, R², R³ and R⁴ is independently an unsubstituted or substituted C₆-C₃₀ aryl group or an unsubstituted or substituted C₃-C₃₀ hetero aryl group.

As used herein, the term “unsubstituted” means that hydrogen is directly linked to a carbon atom. “Hydrogen”, as used herein, can refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, a C₁-C₁₀ alkyl silyl group, a C₁-C₁₀ alkoxy silyl group, a C₃-C₂₀ cyclo alkyl silyl group, a C₆-C₃₀ aryl silyl group, a C₃-C₃₀ hetero aryl silyl group, an unsubstituted or substituted C₆-C₃₀ aryl group, an unsubstituted or substituted C₃-C₃₀ hetero aryl group, and a group formed by any combination of these groups.

As used herein, the term “hetero” in terms such as “a hetero aryl group”, and “a hetero arylene group” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

The C₆-C₃₀ aryl group can independently include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

The C₃-C₃₀ hetero aryl group can independently include, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As an example, each of the aryl group or the hetero aryl group can consist of one to four aromatic and/or hetero aromatic rings. When the number of the aromatic and/or hetero aromatic rings becomes more than four, conjugated structure within the whole molecule becomes too long, thus, the organometallic compound can have too narrow energy bandgap. For example, each of the aryl group or the hetero aryl group can include independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

For example, each of R¹, R², R³ and R⁴ in Chemical Formula 1 can be independently, but is not limited to, selected from phenyl, naphthyl, biphenyl and fluorenyl each of which can be independently unsubstituted or substituted with at least one of a C₁-C₁₀ alkyl group, a C₆-C₂₀ aryl group and a C₃-C₂₀ hetero aryl group. As an example, the first red host (RHH) 442a can include, but is not limited to, at least one of the following compound of Chemical Formula 2:

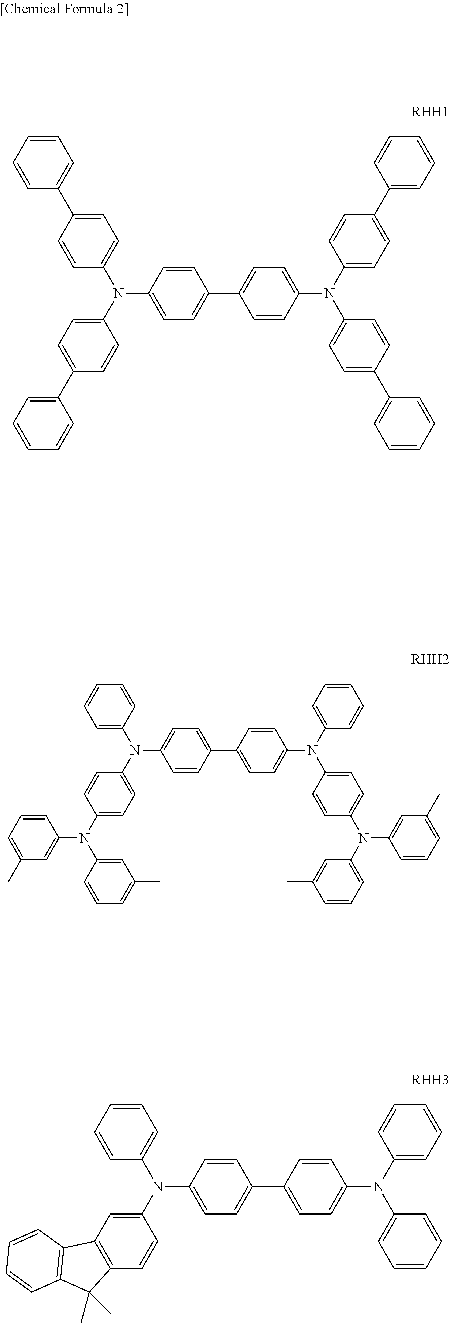 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1 ; CC1(C)c2ccccc2-c2cc(N(c3ccccc3)c3ccc(-c4ccc(N(c5ccccc5)c5ccccc5)cc4)cc3)ccc21]

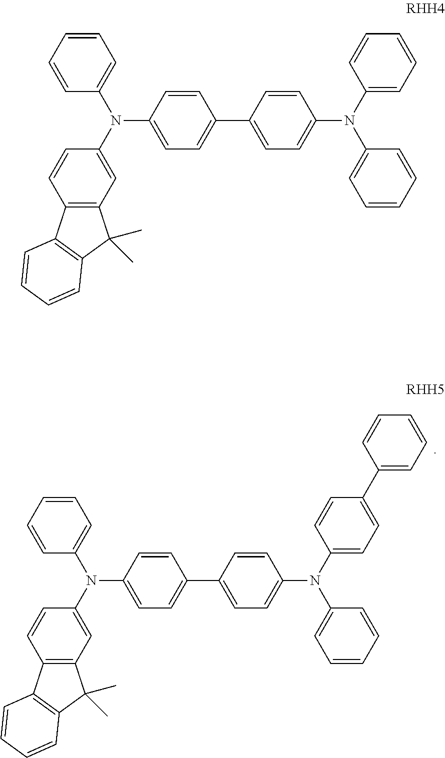 [SMILES: CC1(C)c2ccccc2-c2ccc(N(c3ccccc3)c3ccc(-c4ccc(N(c5ccccc5)c5ccccc5)cc4)cc3)cc21 ; CC1(C)c2ccccc2-c2ccc(N(c3ccccc3)c3ccc(-c4ccc(N(c5ccccc5)c5ccc(-c6ccccc6)cc5)cc4)cc3)cc21]

In another embodiment, the second red host (REH) 444a can include quinazoline-containing compound having the following structure of Chemical Formula 3:

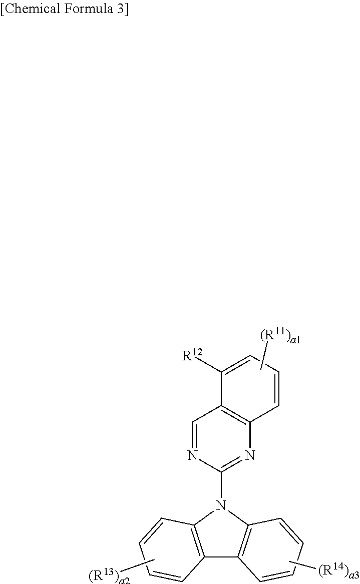

wherein, in Chemical Formula 3,
R¹¹ is hydrogen, an unsubstituted or substituted C₁-C₂₀ alkyl group, an unsubstituted or substituted C₆-C₃₀ aryl group or an unsubstituted or substituted C₃-C₃₀ hetero aryl group, where each R¹¹ is identical to or different from each other when a1 is 2, 3 or 4;
R¹² is hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₆-C₃₀ aryl group or an unsubstituted or substituted C₃-C₃₀ hetero aryl group, where each R¹³ is identical to or different from each other when a2 is 2, 3 or 4, each R¹⁴ is identical to or different from each other when a3 is 2, 3 or 4, or
optionally,
two adjacent R¹³ when a2 is 2, 3 or 4, and/or
two adjacent R¹⁴ when a3 is 2, 3 or 4
can be further linked together to form an unsubstituted or substituted C₆-C₂₀ aromatic ring; and
each of a1, a2 and a3 is independently 0, 1, 2, 3 or 4, where at least one of a2 and a3 is not 0.

In one embodiment, R¹¹ can be hydrogen, R¹² can be phenyl, R¹³ can be hydrogen or two R¹³ can be linked together to form a phenyl ring and/or R¹⁴ can be a carbazolyl or benzo-carbazolyl that can be independently unsubstituted or substituted with phenyl and/or naphthyl, where each of the phenyl and the naphthyl can be independently unsubstituted or further substituted with phenyl and/or naphthyl.

For example, the second red host (REH) 444a of the quinazoline-containing compound can include, but is not limited to, at least one of the following compounds of Chemical Formula 4:

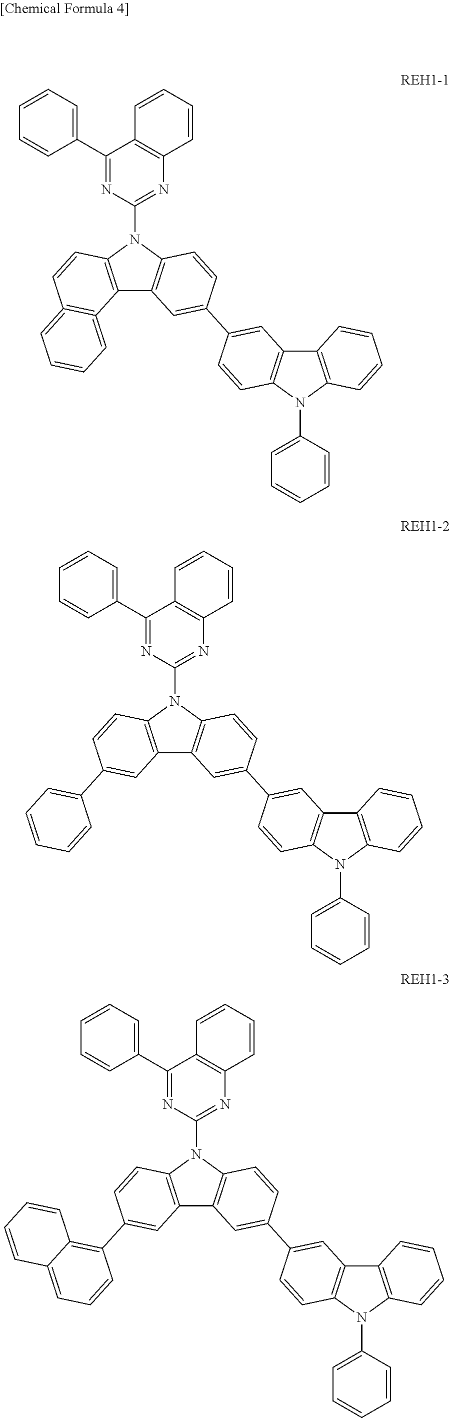

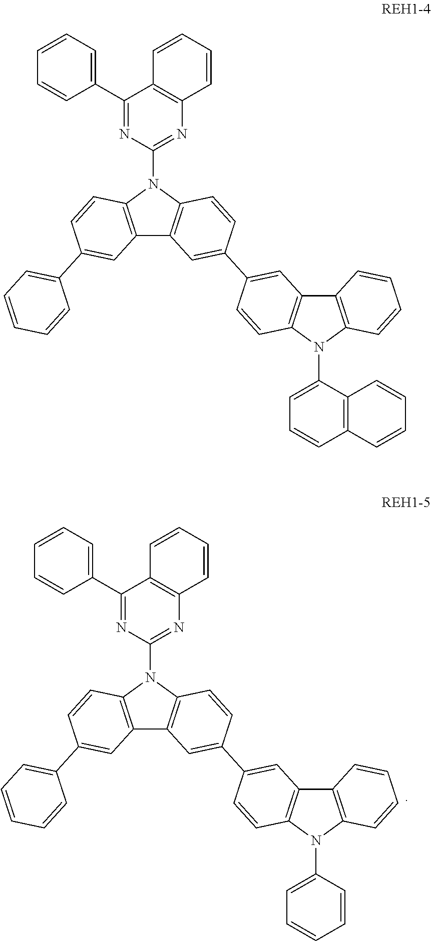 [SMILES: c1ccc(-c2ccc3c(c2)c2cc(-c4ccc5c(c4)c4ccccc4n5-c4cccc5ccccc45)ccc2n3-c2nc(-c3ccccc3)c3ccccc3n2)cc1 ; c1ccc(-c2ccc3c(c2)c2cc(-c4ccc5c(c4)c4ccccc4n5-c4ccccc4)ccc2n3-c2nc(-c3ccccc3)c3ccccc3n2)cc1]

In another embodiment, the second red host (REH) 444a can include a triazine-containing compound having the following structure of Chemical Formula 5:

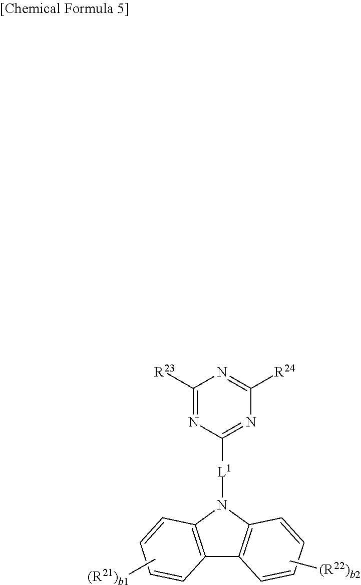

wherein, in Chemical Formula 5,
each of R²¹ and R²² is independently an unsubstituted or substituted C₁-C₂₀ alkyl group, an unsubstituted or substituted C₆-C₃₀ aryl group or an unsubstituted or substituted C₃-C₃₀ hetero aryl group, where at least one of R²¹ and R²² includes an unsubstituted or substituted carbazolyl moiety, each R²¹ is identical to or different from each other when b1 is 2, 3 or 4 and each R²² is identical to or different from each other when b2 is 2, 3 or 4;
each of R²³ and R²⁴ is independently an unsubstituted or substituted C₆-C₃₀ aryl group;
L¹ is a single bond, an unsubstituted or substituted C₆-C₃₀ arylene group or an unsubstituted or substituted C₃-C₃₀ hetero arylene group; and
each of b1 and b2 is independently 0, 1, 2, 3 or 4.

For example, each of the C₁-C₂₀ alkyl group, the C₆-C₃₀ aryl group, the C₃-C₃₀ hetero aryl group, the C₆-C₃₀ arylene group and the C₃-C₃₀ hetero arylene group of R²¹ to R²⁴ and L¹ in Chemical Formula 5 can be independently unsubstituted or substituted with at least one of a C₆-C₃₀ aryl group and a C₃-C₃₀ hetero aryl group.

In one embodiment, R²¹ can be a C₆-C₂₀ aryl group (e.g., phenyl), R²² can be an unsubstituted or phenyl-substituted carbazolyl group, each of R²³ and R²⁴ can be independently an unsubstituted or carbazolyl-substituted C₆-C₂₀ aryl group (e.g., phenyl or naphthyl), L¹ can be C₆-C₂₀ arylene group (e.g., phenylene), b1 can be 0 or 1 and b2 can be 1, but is not limited thereto.

For example, the second red host (REH) 444a of the triazine-containing compound can include, but is not limited to, at least one of the following compounds of Chemical Formula 6:

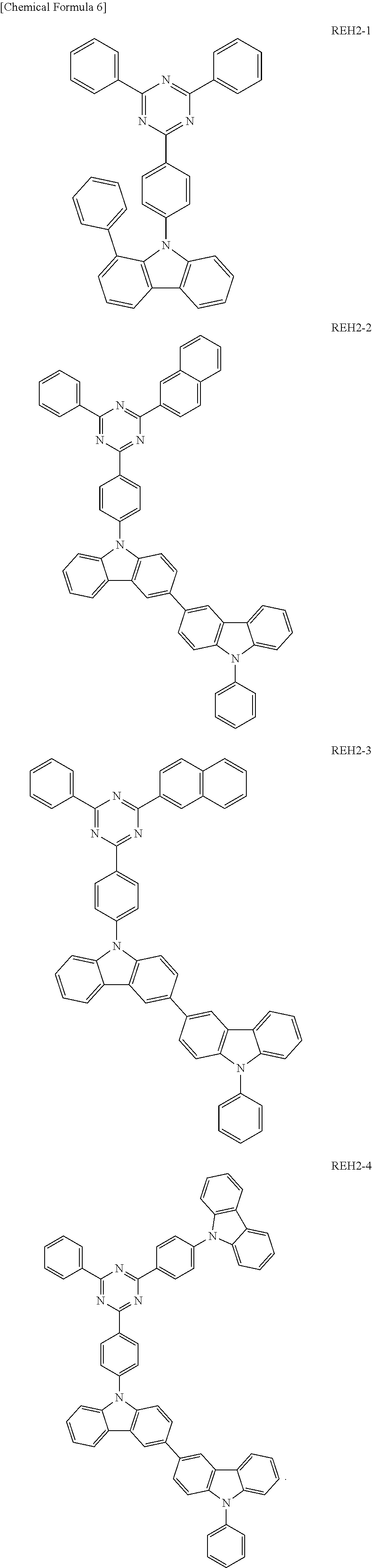

The red emitter 446a can include at least one of a red phosphorescent material, a red fluorescent material and a red delayed fluorescent material. For example, the red emitter 446a can include, but is not limited to, Bis[2-(4,6-dimethyl)phenylquinoline](2,2,6,6-tetramethylheptane-3,5-dionate)iridium(III), Bis[2-(4-n-hexylphenyl)quinoline](acetylacetonate)iridium(III) (Hex-Ir(phq)₂(acac)), Tris[2-(4-n-hexylphenyl)quinoline]iridium(III) (Hex-Ir(phq)₃), Tris[2-phenyl-4-methylquinoline]iridium(III) (Jr(Mphq)₃), Bis(2-phenylquinoline)(2,2,6,6-tetramethylheptene-3,5-dionate)iridium(III) (Jr(dpm)PQ₂), Tris(1-phenylisoquinoline)iridium(III) (Ir(piq)₃), Bis(phenylisoquinoline)(2,2,6,6-tetramethylheptene-3,5-dionate)iridium(III) (Ir(dpm)(piq)₂), Bis(1-phenylisoquinoline)(acetylacetonate)iridiurm(III) (Ir(piq)₂(acac)), Bis[(4-n-hexylphenyl)isoquinoline](acetylacetonate)iridium(III) (Hex-Ir(piq)₂(acac)), Tris[2-(4-n-hexylphenyl)quinoline]iridium(III) (Hex-Ir(piq)₃), Tris(2-(3-methylphenyl)-7-methyl-quinolato)iridium (Ir(dmpq)₃), Bis[2-(2-methylphenyl)-7-methyl-quinoline](acetylacetonate)iridium(III) (Ir(dmpq)₂(acac)), Bis[2-(3,5-dimethylphenyl)-4-methyl-quinoline](acetylacetonate)iridium(III) (Jr(mphmq)₂(acac)), Tis(dibenzoyimethane)mono(1,0-phenanthroline)europiuin(III) (Eu(dbM)₃(phen)) and/or combinations thereof.

In another embodiment, the red emitter 446a can include a phosphorescent material having the following structure of Chemical Formula 7:

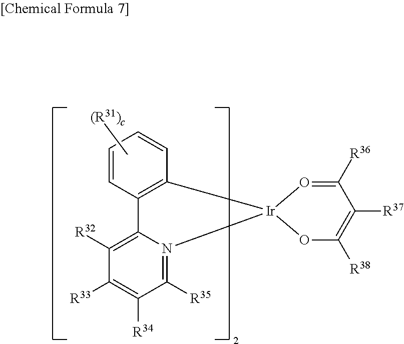

wherein, in Chemical Formula 7,
R³¹ is hydrogen, halogen, an unsubstituted or substituted C₁-C₁₀ alkyl group, an unsubstituted or substituted C₃-C₂₀ cyclo alkyl group, an unsubstituted or substituted C₆-C₃₀ aryl group or an unsubstituted or substituted C₃-C₃₀ hetero aryl group, where each R³¹ is identical to or different from each other when c is 2, 3 or 4;
Each of R³², R³³, R³⁴ and R³⁵ is independently hydrogen, halogen, an unsubstituted or substituted C₁-C₁₀ alkyl group, an unsubstituted or substituted C₃-C₂₀ cyclo alkyl group, an unsubstituted or substituted C₆-C₃₀ aryl group or an unsubstituted or substituted C₃-C₃₀ hetero aryl group, or,
optionally,
two adjacent groups among R³², R³³, R³⁴ and R³⁵ can be further linked together to form an unsubstituted or substituted C₆-C₂₀ aromatic ring;
each R³⁶, R³⁷ and R³⁸ is independently hydrogen or an unsubstituted or substituted C₁-C₂₀ alkyl group; and
c is a number of a substituent and 0, 1, 2, 3 or 4.

For example, R³¹ can be hydrogen or a C₁-C₁₀ alkyl group and/or each of R³² to R³⁵ can be independently hydrogen or two adjacent groups among R³² to R³⁵ be further linked together to form a phenyl ring. As an example, the red emitter 446a having the structure of Chemical Formula 7 can include, but is not limited to, at least one of the following compounds of Chemical Formula 8:

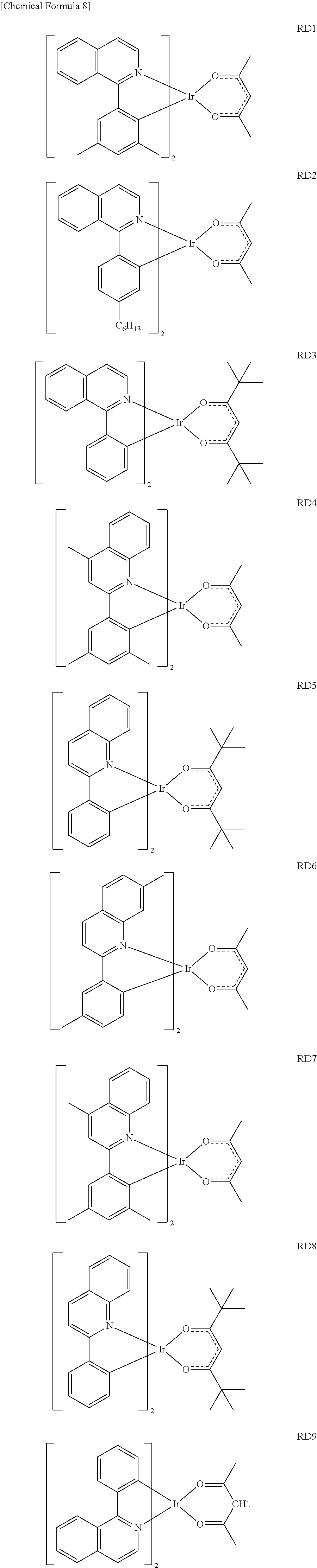

The contents of the red host including the first red host 442a and the second red host 444a in the first layer 440A can be between about 50 wt. % to about 99 wt. %, for example, about 80 wt. % to about 98 wt. %, and the contents of the red emitter 446a in the first layer 440A can be between about 1 wt. % to about 50 wt. %, for example, about 2 wt. % to about 20 wt. %, but is not limited thereto.

In another embodiment, each of the first yellow-green host (YGHH) 442b and the first green host (GHH) 442c can independently include a biscarbazole-containing compound having the following structure of Chemical Formula 9.

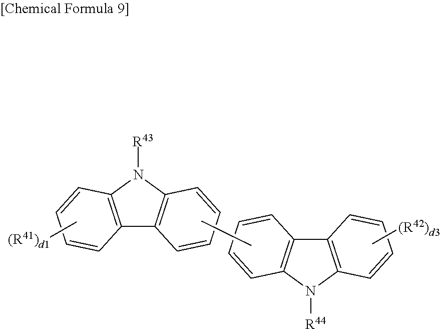

wherein, in Chemical Formula 9,
each of R⁴¹, R⁴², R⁴³ and R⁴⁴ is independently an unsubstituted or substituted C₆-C₃₀ aryl group or an unsubstituted or substituted C₃-C₃₀ hetero aryl group, where each R⁴¹ is identical to or different from each other when d1 is 2, 3 or 4 and each R⁴² is identical to or different from each other when d3 is 2, 3 or 4, or, optionally, each of the unsubstituted or substituted C₆-C₃₀ aryl group and the unsubstituted or substituted C₃-C₃₀ hetero aryl independently forms a spiro structure with an unsubstituted or substituted C₆-C₂₀ aromatic ring or an unsubstituted or substituted C₃-C₂₀ hetero aromatic ring; and
each of d1 and d3 is independently 0, 1, 2, 3 or 4.

For example, each of the C₆-C₃₀ aryl group and the C₃-C₃₀ hetero aryl group of R⁴¹ to R⁴⁴ can be independently unsubstituted or substituted with at least one of a C₁-C₁₀ alkyl group, cyano, a C₁-C₁₀ alkyl silyl group, a C₆-C₂₀ aryl silyl group, a C₆-C₂₀ aryl group and a C₃-C₂₀ hetero aryl group, or form a spiro structure with a C₆-C₂₀ aromatic ring or a C₃-C₂₀ hetero aromatic ring.

As an example, two carbazole moieties of the biscarbazole-containing compound in Formula 9 as the first yellow-green host (YGHH) 442b and/or the first green host (GHH) 442c can be linked to, but is not limited to, 3-position of each carbazole moiety. For example, each of R⁴¹ to R⁴⁴ in Chemical Formula 9 can include, but is not limited to, an aryl group such as phenyl, biphenyl, terphenyl, naphthyl (e.g., 1-naphtyl or 2-naphthyl), fluorenyl (e.g., 9,10-dimenthyl-9H-fluorenyl or spiro-fluorenyl), anthracenyl, pyrenyl and/or triphenylenyl, each of which can be independently unsubstituted or substituted with at least one of cyano, C₆-C₂₀ aryl silyl, C₆-C₂₀ aryl and C₃-C₂₀ hetero aryl.

In one embodiment, each of R⁴¹ to R⁴ can be identical to or different form each other and independently include, but is not limited to, an unsubstituted or substituted phenyl, an unsubstituted or substituted naphthyl and unsubstituted or substituted triphenylenyl. Each of d1 and d3 in Chemical Formula 9 can independently be 0 or 1. In one embodiment, each of the first yellow-green host (YGHH) 442b and/or the first green host (GHH) 442c of the biscarbazole-containing compound can independently, but is not limited to, at least one of the following compounds of Chemical Formula 10:

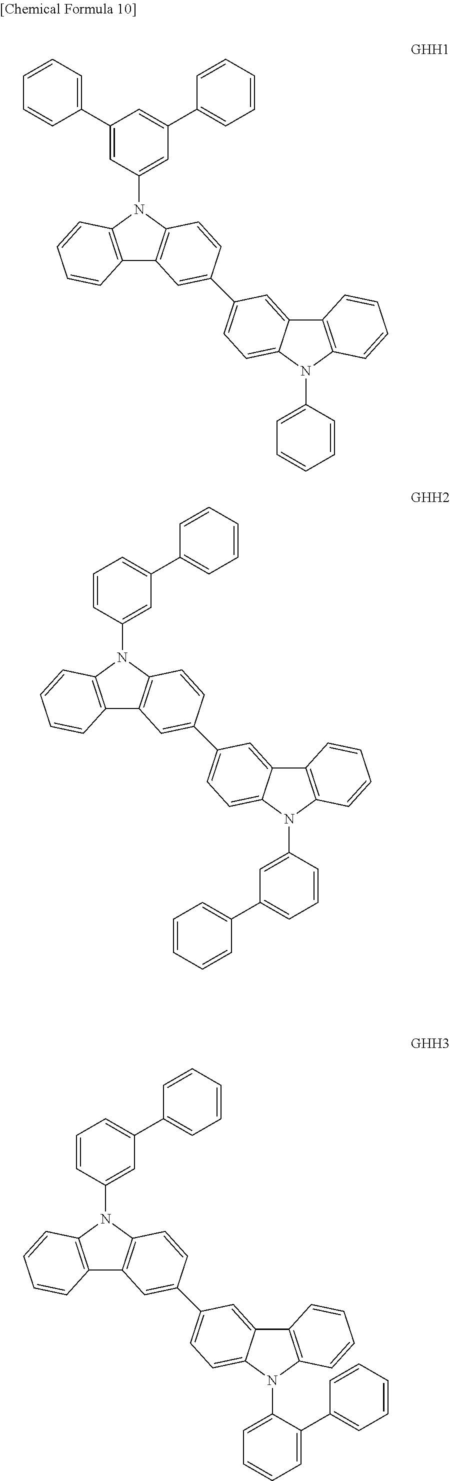 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

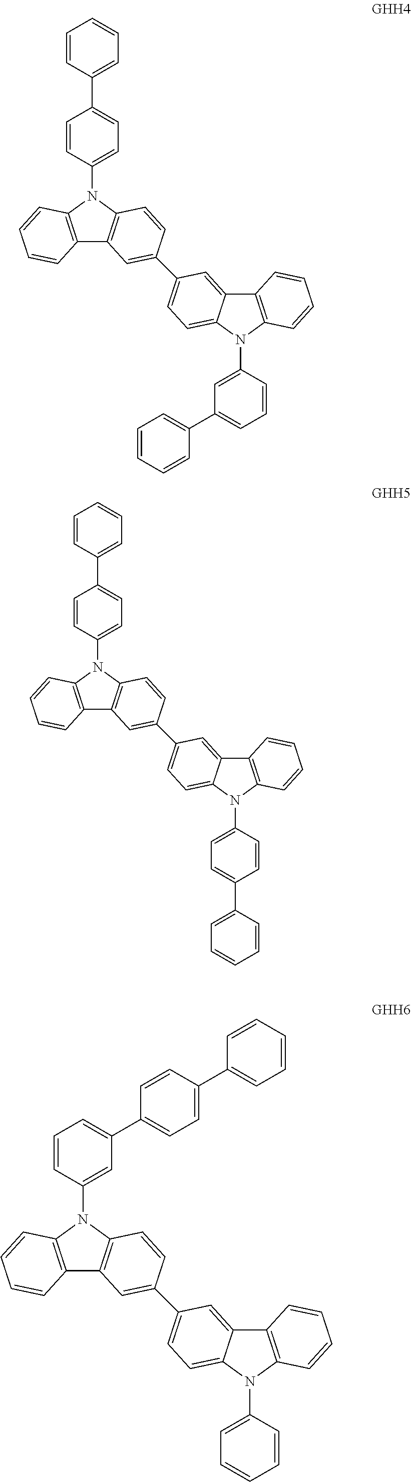 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-c3cccc(-n4c5ccccc5c5cc(-c6ccc7c(c6)c6ccccc6n7-c6ccccc6)ccc54)c3)cc2)cc1]

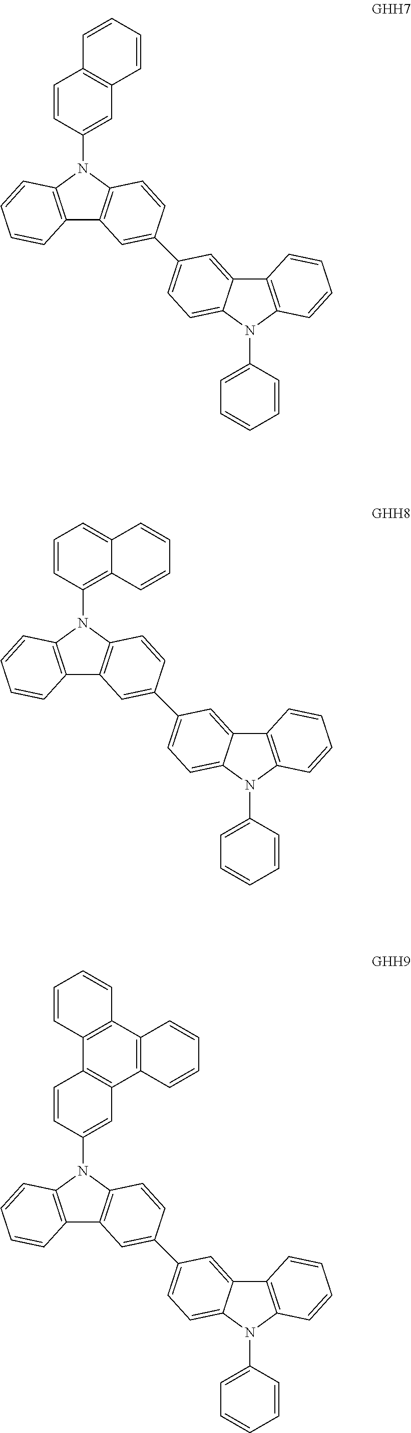 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

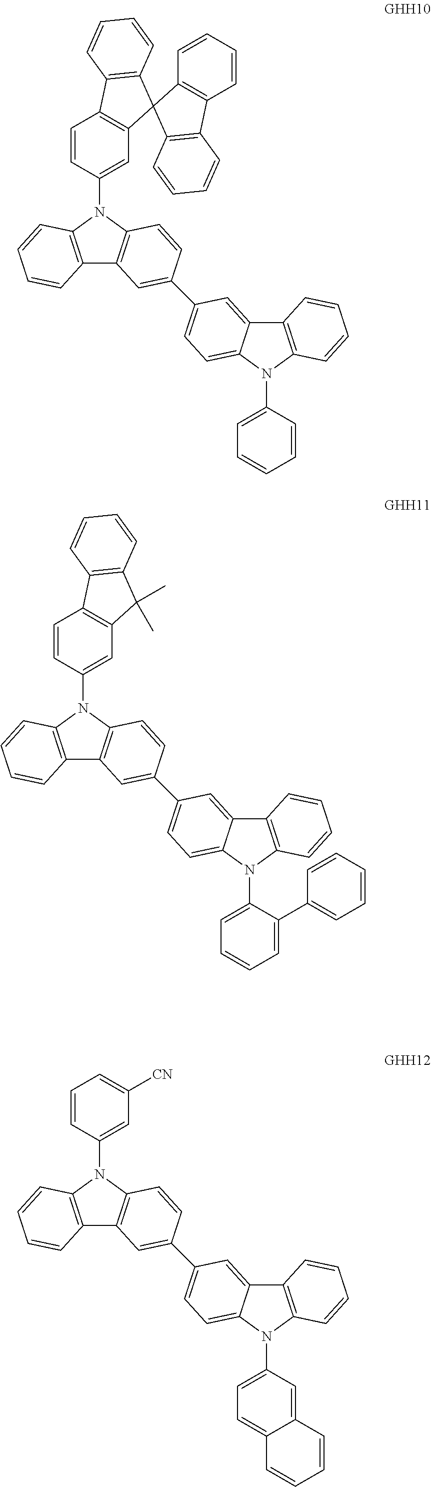 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

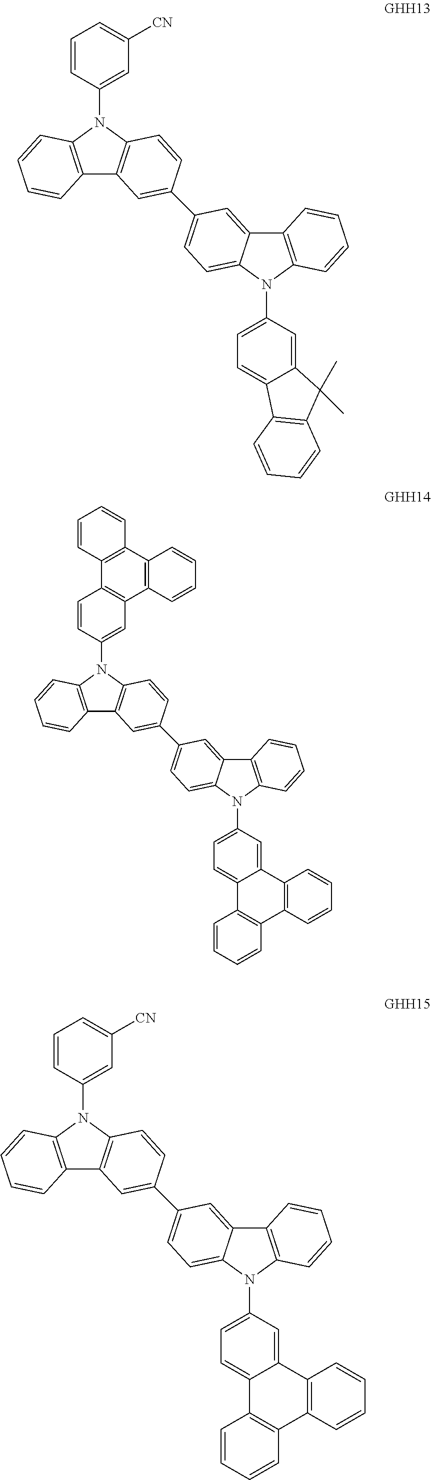 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21 ; N#Cc1cccc(-n2c3ccccc3c3cc(-c4ccc5c(c4)c4ccccc4n5-c4ccc5c6ccccc6c6ccccc6c5c4)ccc32)c1]

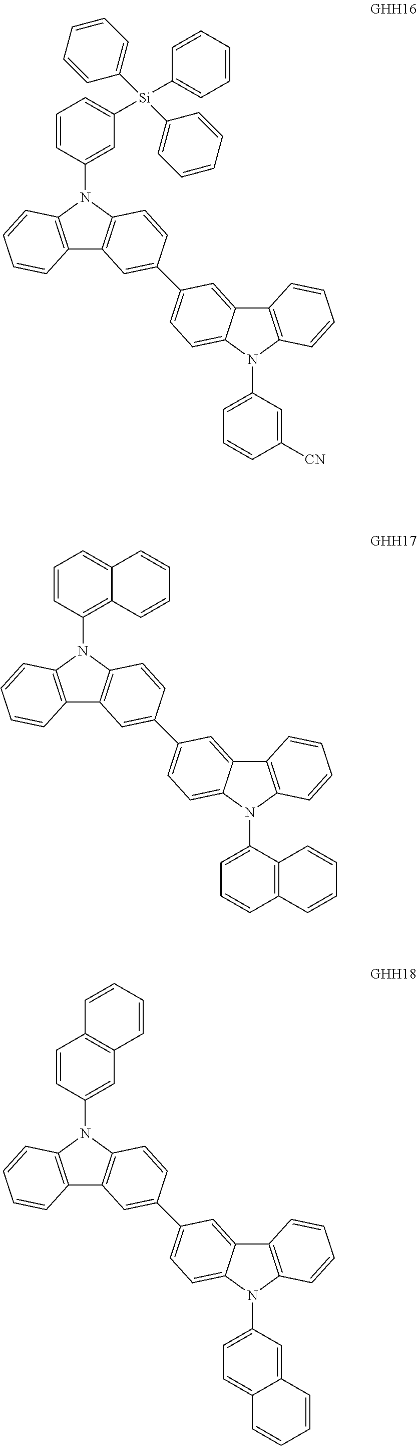 [SMILES: N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1 ; c1ccc2cc(-n3c4ccccc4c4cc(-c5ccc6c(c5)c5ccccc5n6-c5ccc6ccccc6c5)ccc43)ccc2c1]

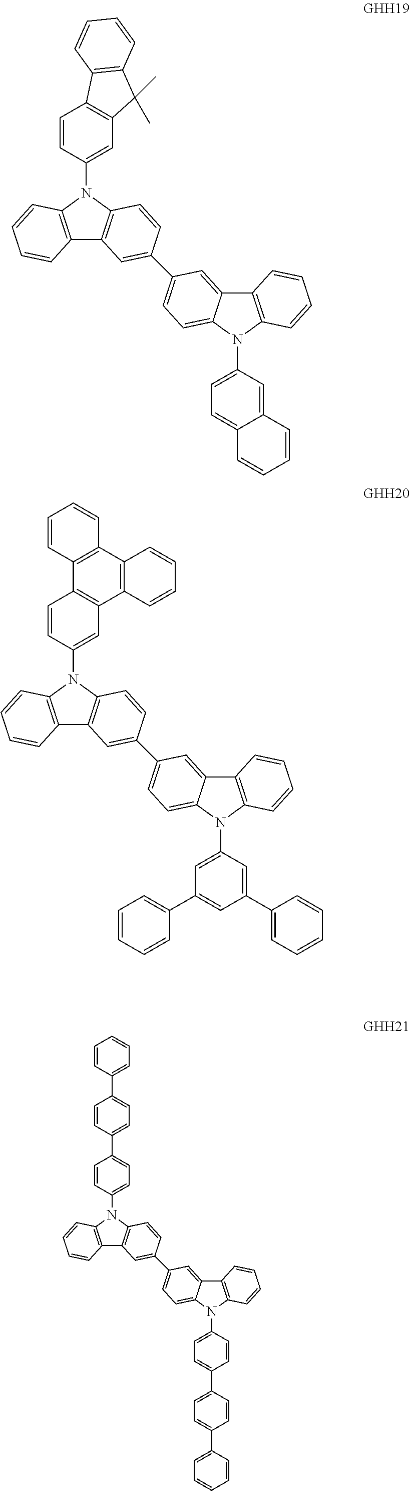 [SMILES: CC1(C)c2ccccc2-c2ccc(-n3c4ccccc4c4cc(-c5ccc6c(c5)c5ccccc5n6-c5ccc6ccccc6c5)ccc43)cc21 ; c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1 ; c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1]

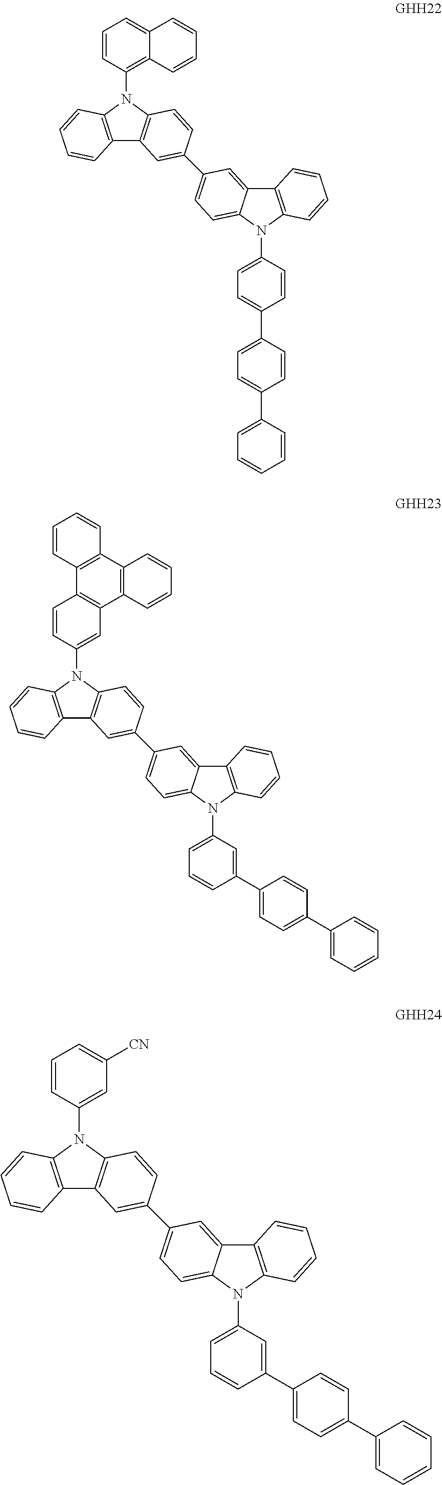 [SMILES: c1ccc(-c2ccc(-c3ccc(-n4c5ccccc5c5cc(-c6ccc7c(c6)c6ccccc6n7-c6cccc7ccccc67)ccc54)cc3)cc2)cc1 ; c1ccc(-c2ccc(-c3cccc(-n4c5ccccc5c5cc(-c6ccc7c(c6)c6ccccc6n7-c6ccc7c8ccccc8c8ccccc8c7c6)ccc54)c3)cc2)cc1 ; N#Cc1cccc(-n2c3ccccc3c3cc(-c4ccc5c(c4)c4ccccc4n5-c4cccc(-c5ccc(-c6ccccc6)cc5)c4)ccc32)c1]

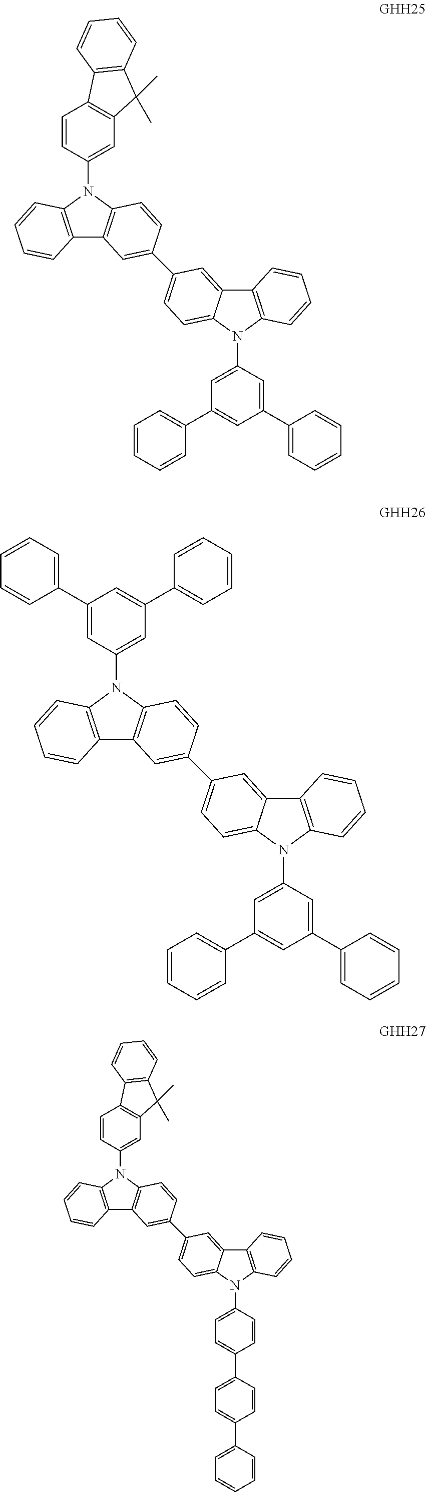 [SMILES: CC1(C)c2ccccc2-c2ccc(-n3c4ccccc4c4cc(-c5ccc6c(c5)c5ccccc5n6-c5cc(-c6ccccc6)cc(-c6ccccc6)c5)ccc43)cc21 ; c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1 ; CC1(C)c2ccccc2-c2ccc(-n3c4ccccc4c4cc(-c5ccc6c(c5)c5ccccc5n6-c5ccc(-c6ccc(-c7ccccc7)cc6)cc5)ccc43)cc21]

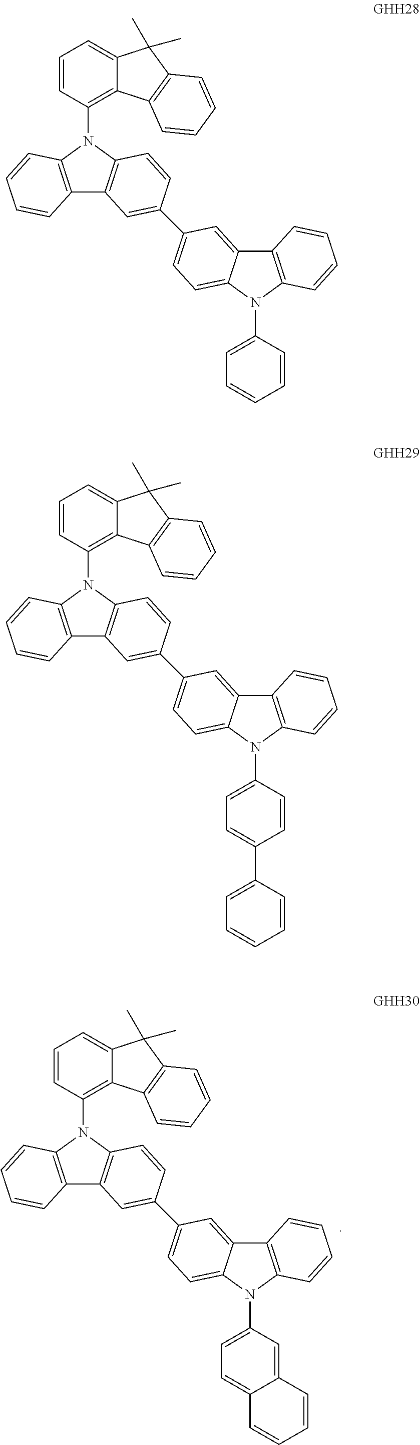 [SMILES: CC1(C)c2ccccc2-c2c(-n3c4ccccc4c4cc(-c5ccc6c(c5)c5ccccc5n6-c5ccccc5)ccc43)cccc21 ; CC1(C)c2ccccc2-c2c(-n3c4ccccc4c4cc(-c5ccc6c(c5)c5ccccc5n6-c5ccc(-c6ccccc6)cc5)ccc43)cccc21 ; CC1(C)c2ccccc2-c2c(-n3c4ccccc4c4cc(-c5ccc6c(c5)c5ccccc5n6-c5ccc6ccccc6c5)ccc43)cccc21]

In another embodiment, each of the second yellow-green host (YGEH) 444b and/or the second green host (GEH) 444c can independently include at least one of electron transporting material and hole blocking material (e.g., TPBi) described below.

In another embodiment, each of the second yellow-green host (YGEH) 444b and/or the second green host (GEH) 444c can include, but is not limited to, Bis[2-(diphenylphosphino)phenyl]ether oxide (DPEPO), 1,3,5-Tri[(3-pyridyl)-phen-3-yl]benzene (TmPyPB), 2,6-Di(9H-carbazol-9-yl)pyridine (PYD-2Cz), Diphenyl-4-triphenylsilyl-phenylphosphine oxide (TSPO1), the azine-containing compound having the following structure of Chemical Formula 11 and/or combinations thereof.

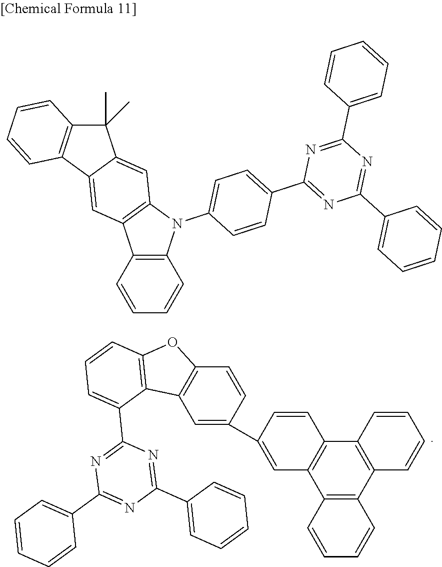

The yellow-green emitter 446b can include at least one of a yellow-green phosphorescent material, a yellow-green fluorescent material and a yellow-green delayed fluorescent material. For example, the yellow-green emitter 446b can include, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)irdium(III) (Ir(BT)₂(acac)), Bis(2-(9,9-diethyl-fluoren-2-yl)-1-phenyl-1H-benzo[d]imdiazolato)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQIrpic), Bis(4-phenylthieno[3,2-c]pyridinato-N,C2′) (acetylacetonate) iridium(III) (PO-01) and/or combinations thereof.

The contents of the yellow-green host including the first yellow-green host 442b and the second yellow-green host 444b in the second layer 440B can be between about 50 wt. % to about 99 wt. %, for example, about 80 wt. % to about 98 wt. %, and the contents of the yellow-green emitter 446b in the second layer 440B can be between about 1 wt. % to about 50 wt. %, for example, about 2 wt. % to about 20 wt. %, but is not limited thereto.

The green emitter 446c can include at least one of a green phosphorescent material, a green fluorescent material and a green delayed fluorescent material. For example, the green emitter 446c can include, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tri s[2-(p-tolyl)pyridine]iridium(III) (Ir(mppy)₃), Bis(2-(naphthalene-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof.

The contents of the green host including the first green host 442c and the second green host 444c in the third layer 440C can be between about 50 wt. % to about 99 wt. %, for example, about 80 wt. % to about 98 wt. %, and the contents of the green emitter 446c in the third layer 440C can be between about 1 wt. % to about 50 wt. %, for example, about 2 wt. % to about 20 wt. %, but is not limited thereto.

Returning to FIG. 3, the EML1 340 can be a blue emitting material layer. In this case, the EML1 340 can be a blue emitting material layer, a sky-blue emitting material layer and/or a deep blue emitting material layer. The EML1 340 can include a blue host and a blue emitter.

The blue host can include at least one of a P-type blue host and an N-type blue host. For example, the blue host can include, 1,3-Bis(carbazol-9-yl)benzene (mCP), 9-(3-(9H-carbazol-9-yl)phenyl)-9H-carbazole-3-carbonitrile (mCP-CN), 3,3-Di(9H-carbazol-9-yl)biphenyl (mCBP), CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1,9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spirobifluoren-2-yl-diphenyl-phosphine oxide (SPPO1), 9,9′-(5-(Triphenylsilyl)-1,3-phenylene)bis(9H-carbazole) (SimCP), 9,10-di(naphthalen-2-yl)anthracene (ADN), 2-methyl-9,10-bis(naphthalen-2-yl)anthracene (MADN), 2-tert-Butyl-9,10-di(naphthen-2-yl)anthracene (TBADN), 9,10-di(naphthalen-2-yl)-2-phenylanthracene (PADN), 9,10-di(1-naphthyl)anthracene, 9-(naphthalene-1-yl)-10-(naphthalene-2-yl)anthracene, 9-(2-napthyl)-10-[4-(1-naphthyl)phenyl]anthracene, 9-(1-napthyl)-10-[4-(2-naphthyl)phenyl]anthracene, 9-phenyl-10-(p-tolyl)anthracene (PTA), 9-(1-naphthyl)-10-(p-tolyl)anthracene (1-NTA), 9-(2-naphthyl)-10-(p-tolyl)anthracene (2-NTA) and/or combinations thereof.

The blue emitter can include at least one of a blue phosphorescent material, a blue fluorescent material and a blue delayed fluorescent material, for example, boron-containing compound. For example, the blue emitter can include pyrene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-Tetra-tetr-butylperylene (TBPe), Bis((2-hydroxylphenyl)-pyridine)beryllium (Bepp₂), 9-(9-Phenylcarbazol-3-yl)-10-(naphthalen-1-yl)anthracene (PCAN), mer-Tris(1-phenyl-3-methylimidazolin-2-ylidene-C,C(2)′)iridium(III) (mer-Ir(pmi)₃), fac-Tris(1,3-diphenyl-benzimidazolin-2-ylidene-C,C(2)′)iridium(III) (fac-Ir(dpbic)₃), Bis(3,4,5-trifluoro-2-(2-pyridyl)phenyl-(2-carboxypyridyl))iridium(III) (Ir(tfpd)₂pic), tris(2-(4,6-difluorophenyl)pyridine)iridium(III) (Ir(Fppy)₃), Bis[2-(4,6-difluorophenyl)pyridinato-C²,N](picolinato)iridium(III) (FIrpic), DABNA-1, DABNA-2, t-DABNA, v-DAB1NA, the compound having the following structure of Chemical Formula 12 and/or combinations thereof.

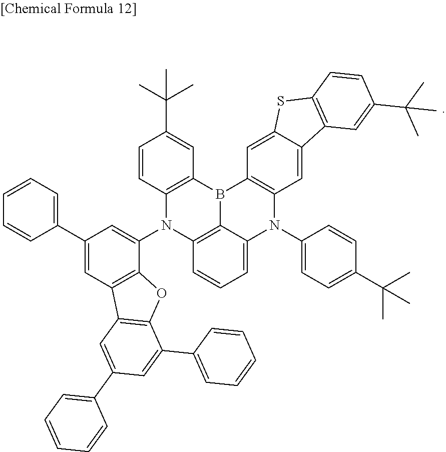 [SMILES: CC(C)(C)c1ccc(N2c3cc4c(cc3B3c5cc(C(C)(C)C)ccc5N(c5cc(-c6ccccc6)cc6c5oc5c(-c7ccccc7)cc(-c7ccccc7)cc56)c5cccc2c53)sc2ccc(C(C)(C)C)cc24)cc1]

In one embodiment, the contents of the blue host in the EML1 340 can be between about 50 wt. % to about 99 wt. %, for example, about 80 wt. % to about 98 wt. %, and the contents of the blue emitter in the EML1 340 can be between about 1 wt. % to about 50 wt. %, for example, about 2 wt. % to about 20 wt. %, but is not limited thereto. When the EML1 340 includes the P-type blue host and the N-type blue host, the P-type blue host and the N-type blue host can be mixed with, but is not limited to, a weight ratio of about 4:1 to about 1:4, for example, about 3:1 to about 1:3.

The HIL 310 is disposed between the first electrode 210 and the HTL1 320 and can improve an interface property between the inorganic first electrode 210 and the organic HTL1 320. In one embodiment, hole injecting material in the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-nethlphenyl)amnino]phenylI}-N,N′-diphenyl-4,4′-biplhenydianine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-Tetrafluoro-7,7,8,8-tetracyano-quinodimethane (F4-TCNQ), 1,3,4,5,7,8-hexafluoro-tetracyano-naphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB), Di-[4-(N,N-di-p-tolyl-amino)-phenyl]cyclohexane (TAPC), N4,N4,N4′,N4′-Tetra[(1,1′-biphenyl)-4-yl]-(1,1′-biphenyl)-4,4′-diamine (BPBPA), MgF₂, CaF₂, and/or combinations thereof.

In another embodiment, the HIL 310 can include the hole transporting material described below doped with the above hole injecting material (e.g., organic material such as HAT-CN, F4-TCNQ and/or F6-TCNNQ and/or inorganic material such as MgF₂ and/or CaF₂). In this case, the contents of the hole injecting material in the HIL 310 can include, but is not limited to, about 1 wt. % to about 50 wt. %, for example, about 5 wt. % to about 50 wt. %. In certain embodiments, the HIL 310 can be omitted in compliance of the OLED D1 property.

Each of the HTL1 320 and the HTL2 420 provides holes to each of the EML1 340 and the EML2 440, respectively. In one embodiment, each of the hole transporting material in the HTL1 320 and the HTL2 420 can independently include, but is not limited to, N,N′-Diphenyl-N,N′-bis(3-methylphenyl)-1,1′-biphenyl-4,4′-diamine (TPD), NPB(NPD), 4,4′-bis(N-carbazolyl)-1,1′-biphenyl (CBP), DNDPD, BPBPA, NBNPB, Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), TAPC, 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combinations thereof.

Each of the ETL1 360 and the ETL2 460 provides electrons to each of the EML1 340 and the EML2 440, respectively. An electron transporting material included in the ETL1 360 and the ETL2 460 has high electron mobility so as to provide electrons stably with the EML1 340 and the EML2 440 by fast electron transportation.

In one embodiment, each of electron transporting materials in the ETL1 360 and the ETL2 460 can independently include at least one of an oxadiazole-containing compound, a triazole-containing compound, a phenanthroline-containing compound, a benzoxazole-containing compound, a benzothiazole-containing compound, a benzimidazole-containing compound, a triazine-containing compound and/or combinations thereof.

For example, each of the electron transporting materials in the ETL1 360 and the ETL2 460 can independently include, but is not limited to, tris-(8-hydroxyquinoline) aluminum (Alq₃), 2-biphenyl-4-yl-5-(4-t-butylphenyl)-1,3,4-oxadiazole (PBD), spiro-PBD, lithium quinolate (Liq), 2,2′,2″-(1,3,5-benzenetriyl)-tris(1-phenyl-1-H-benzimidazole) (TPBi), Bis(2-methyl-8-quinolinolato-N1,08)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] dibromide (PFNBr), tris(phenylquinoxaline) (TPQ), Diphenyl-4-triphenylsilyl-phenylphosphine oxide (TSPO1), 2-[4-(9,10-Di-2-naphthalen2-yl-2-anthracen-2-yl)phenyl]-1-phenyl-1H-benzimidazole (ZADN), the compound having the following structure of Chemical Formula 13 and/or combinations thereof.

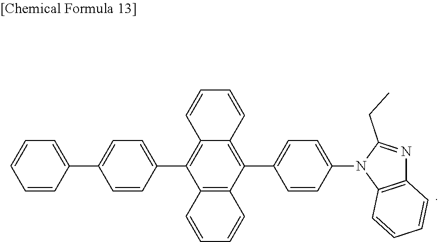 [SMILES: CCc1nc2ccccc2n1-c1ccc(-c2c3ccccc3c(-c3ccc(-c4ccccc4)cc3)c3ccccc23)cc1]

The EIL 470 is disposed between the second electrode 220 and the ETL2 460, and can improve physical properties of the second electrode 220 and therefore, can enhance the lifespan of the OLED D1. In one embodiment, electron injecting material in the EIL 470 can include, but is not limited to, an alkali metal halide and/or an alkaline earth metal halide such as LiF, CsF, NaF, BaF₂ and the like, and/or an organometallic compound such as Liq, lithium benzoate, sodium stearate, and the like. In certain embodiments, the EIL 470 can be omitted.

In another embodiment, the ETL2 460 and the EIL 470 can be formed with a single layer with mixing the electron transporting material and/or the electron injecting material. For example, the ETL2/ETL with a single layered structure can include two or more different electron transporting material. In this case, two or more electron transporting materials in the ETL2/EIL can be mixed, but is not limited to, a weight ratio of about 3:7 to about 7:3.

When holes are transferred to the second electrode 220 via the EML1 340 and/or the EML2 440, or electrons are transferred to the first electrode 210 via the EML1 340 and/or the EML2 440, the OLED D1 can have short lifespan and reduced luminous efficiency. In order to prevent such phenomena, the OLED D1 in accordance with one embodiment can further include at least one exciton blocking layer disposed adjacently to the EML1 340 and/or the EML2 440.

For example, the OLED D1 can further include the EBL 330 between the HTL1 320 and the EML1 340 and/or the EBL2 430 between the HTL2 420 and the EML2 440 so as to control and prevent electron transportation. As an example, each of electron blocking material in the EBL1 330 and the EBL2 430 can independently include, but is not limited to, TCTA, N-(biphenyl-4-yl)-9,9-dimethyl-N-(4-(9-phenyl-9H-carbazol-3-yl)phenyl)-9H-fluoren-2-amine, TAPC, MTDATA, mCP CuPc, DNTPD, TDABP, DCDPA, 2,8-bis(9-phenyl-9H-carbazol-3-yl)dibenzo[b,d]thiophene and/or combinations thereof.

In addition, the OLED D1 can further include the HBL1 350 between the EML1 340 and the ETL1 360 and/or the HBL2 450 between the EML2 440 and the ETL2 460 so that holes cannot be transferred from the EML1 340 and/or the EML2 440 to the ETL1 360 and/or the ETL2 460. In one embodiment, each of hole blocking materials in the HBL1 350 and the HBL2 450 can independently include, but is not limited to, at least one of an oxadiazole-containing compound, a triazole-containing compound, a phenanthroline-containing compound, a benzoxazole-containing compound, a benzothiazole-containing compound, a benzimidazole-containing compound, and a triazine-containing compound.

For example, each of the hole blocking materials in the HBL1 350 and the HBL2 450 can independently include material having a relatively low HOMO energy level compared to the luminescent materials in EML1 340 and/or the EML2 440. Each of the hole blocking materials in the HBL1 350 and the HBL2 450 can independently include, but is not limited to, BCP, BAlq, Alq₃, PBD, spiro-PBD, Liq, Bis-4,5-(3,5-di-3-pyridylphenyl)-2-methylpyrimidine (B3PYMPM), Bis[2-(diphenylphosphino)phenyl]ether oxide (DPEPO), 9-(6-(9H-carbazol-9-yl)pyridine-3-yl)-9H-3,9′-bicarbazole, TSPO1 and/or combinations thereof. In certain embodiments, each of the EBL1 330 and the EBL2 430 and/or the HBL1 350 and the HBL2 450 can be omitted.

The CGL 380 includes an N-type charge generation layer (N-CGL) 385 disposed between the ETL1 360 and the HTL2 420 and a P-type charge generation layer (P-CGL) 390 disposed between the N-CGL 385 and the HTL2 420. The N-CGL 385 provides electrons to the EML1 340 of the first emitting part 300 and the P-CGL 390 provides holes to the EML2 440 of the second emitting part 400.

N-CGL 385 can be an organic layer with electron transporting material doped with an alkali metal such as Li, Na, K and Cs and/or an alkaline earth metal such as Mg, Sr, Ba and Ra. For example, the contents of the alkali metal and/or the alkaline earth metal in the N-CGL 385 can include, but is not limited to, between about 0.1 wt. % and about 30 wt. %, for example, about 1 wt. % and about 10 wt. %.

In one embodiment, the P-CGL 390 can include, but is not limited to, inorganic material selected from the group consisting of WOₓ, MoOₓ, Be₂O₃, V₂O₅ and/or combinations thereof. In another embodiment, the P-CGL 390 can include organic material of the hole transporting material doped with the hole injecting material (e.g., organic material such as HAT-CN, F4-TCNQ and/or F6-TCNNQ). In this case, the contents of the hole injecting material in the P-CGL 390 can include, but is not limited to, between about 2 wt. % and about 15 wt. %.

As described above, the thicknesses of the first layer 440A of the red emitting material layer, the second layer 440B of the yellow-green emitting material layer and the third layer 440C of the green emitting material layer are controlled so that the color temperature of the white light and color gamut can be improved. The contents and/or energy levels of the hosts 442a, 444a, 442b, 444b, 442c and/or 444c in the first to third layers 440A to 440C are controlled so that the emission area can be distributed uniformly within the entire area of the EML2 440. The degradations of the luminous materials and charge transporting materials caused by excessively generated excitons at particular areas and/or non-emitting excitons can be prevented, and thus, the luminous lifespan of the OLED D1 can be improved significantly with maintaining the luminous efficiency of the OLED D1. In certain embodiments, the OLED D1 can include only the second emitting part 400 without the first emitting part 300 and the CGL 380.

An example of the OLED D of FIG. 2 is shown in FIG. 7 as an OLED D2. Particularly, FIG. 7 illustrates a schematic cross-sectional view of an organic light emitting diode having a tandem structure of three emitting parts.

As illustrated in FIG. 7, the OLED D2 in accordance with another embodiment includes first and second electrodes 210 and 220 facing each other and an emissive layer 230 Å disposed between the first and second electrodes 210 and 220. The emissive layer 230 Å includes a first emitting part 300 disposed between the first and second electrodes 210 and 220, a second emitting part 400A disposed between the first emitting part 300 and the second electrode 220, a third emitting part 500 disposed between the second emitting part 400A and the second electrode 220, a first charge generation layer (CGL1) 380 disposed between the first emitting part 300 and the second emitting part 400A, and a second charge generation layer (CGL2) 480 disposed between the second emitting part 400A and the third emitting part 500.

The first emitting part 300 includes a first emitting material layer (EML1) 340. The first emitting part 300 can include at least one of a first hole transport layer (HTL1) 320 disposed between the first electrode 210 and the EML1 340 and a first electron transport layer (ETL1) 360 disposed between the EML1 340 and the CGL1 380. The first emitting part 300 can further include a hole injection layer (HIL) 310 disposed between the first electrode 210 and the HTL1 320. Alternatively, or additionally, the first emitting part 300 can further include a first electron blocking layer (EBL1) 330 disposed between the HTL1 320 and the EML1 340 and/or a first hole blocking layer (HBL1) 350 disposed between the EML1 340 and the ETL1 360.

The second emitting part 400A includes a second emitting material layer (EML2) 440. The second emitting part 400A can include at least one of a second hole transport layer (HTL2) 420 disposed between the CGL1 380 and the EML2 440 and a second electron transport layer (ETL2) 460 disposed between the EML2 440 and the CGL2 480. Alternatively, or additionally, the second emitting part 400A can further include at least one of a second electron blocking layer (EBL2) 430 disposed between the HTL2 420 and the EML2 440 and/or a second hole blocking layer (HBL2) 450 disposed between the EML2 440 and the ETL2 460.

The third emitting part 500 includes a third emitting material layer (EML3) 540. The third emitting part 500 can include at least one of a third hole transport layer (HTL3) 520 disposed between the CGL2 480 and the EML3 540 and a third electron transport layer (ETL3) 560 disposed between the EML4 540 and the second electrode 220. The third emitting part 500 can further include an electron injection layer (EIL) 570 disposed between the ETL3 560 and the second electrode 220. Alternatively, or additionally, the third emitting part 500 can further include at least one of a third electron blocking layer (EBL3) 530 disposed between the HTL3 520 and the EML3 540 and a third hole blocking layer (HBL3) 550 disposed between the EML3 540 and the ETL3 560.

The CGL1 380 is disposed between the first emitting part 300 and the second emitting part 400A, and the CGL2 480 is disposed between the second emitting part 400A and the third emitting part 500. The CGL1 380 includes a first N-type charge generation layer (N-CGL1) 385 disposed between the ETL1 360 and the HTL2 420, and a first P-type charge generation layer (P-CGL1) 390 disposed between the N-CGL1 385 and the HTL2 420. The CGL2 480 includes a second N-type charge generation layer (N-CGL2) 485 disposed between the ETL2 460 and the HTL3 520, and a second P-type charge generation layer (P-CGL2) 490 disposed between the N-CGL2 485 and the HTL3 520.

The materials in the HIL 310, the HTL1 to HTL3 320, 420 and 520, the EBL1 to EBL3 330, 430 and 530, the HBL1 to HBL3 350, 450 and 550, the ETL1 to ETL3 360, 460 and 560, the EIL 570, the CGL1 380 and the CGL2 480 can be identical to the corresponding materials with referring to FIGS. 3, 5 and 6. In certain embodiments, the HIL 310, the EBL1 to EBL3 330, 430 and 530, the HBL1 to HBL3 350, 450 and 550 and/or the EIL 570 can be omitted.

At least one of the EML1 to EML3 340, 440 and 540 can emit red, yellow-green and green color lights, and another of the EML1 to EML3 340, 440 and 540 can emit blue color light, so that the OLED D2 can provide white (W) emission. Hereinafter, the OLED D2 where the EML2 440 emits red, yellow-green and green color lights and the EML1 340 and the EML3 540 emit blue color lights will be described in more detail.

Each of the EML1 340 and the EML3 540 can be a first blue emitting material layer and a second blue emitting material layer, respectively. In this case, each of the EML1 340 and the EML3 540 can be independently a blue emitting material layer, a sky-blue emitting material layer and/or a deep blue emitting material layer. Each of the EML1 340 and the EML3 540 can include a blue host and a blue emitter.

The blue host and the blue emitter can be identical to corresponding materials with referring to FIG. 3. For example, the blue emitter can include at least one of a blue phosphorescent material, a blue fluorescent material, and a blue delayed fluorescent material. In another embodiment, the blue host and/or the blue emitter in the EML1 340 can be identical to or different from the blue host and/or the blue emitter in the EML3 540 in terms of color and/or luminous efficiency.

In one embodiment, the contents of the blue host in each of the EML1 340 and the EML3 540 can be between about 50 wt. % and about 99 wt. %, for example, about 80 wt. % and about 98 wt. %. Further, the contents of the blue emitter in each of the EML1 340 and the EML3 540 can be between about 1 wt. % and about 50 wt. %, for example, about 2 wt. % and about 20 wt. %, but is not limited thereto. When each of the EML1 340 and the EML3 540 includes both the P-type blue host and the N-type blue host, the P-type blue host and the N-type blue host can be mixed with, but is not limited to, a weight ratio of about 4:1 to about 1:4, for example, about 3:1 to about 1:3.

The EML2 440 can include a red emitting material layer (first layer, R-EML) 440 Å, a yellow-green emitting material layer (second layer, YG-EML) 440B and a green emitting material layer (third layer, G-EML) 440C disposed sequentially between the CGL1 380 and the second electrode 220, for example, HTL2 420 or the EBL2 430 and the ETL2 460 or the HBL 450.

The first layer 440A can include a first red host 442a and a red emitter (red dopant) 446a, and optionally, a second red host 444a. The second layer 440B can include a first yellow-green host 442b and a yellow-green emitter (yellow-green dopant) 446b, and optionally, a second yellow-green host 444b. The third layer 440C can include a first green host 442c and a green emitter (green dopant) 446c, and optionally, a second green host 444c.

The kinds and the contents of the first red host 442a, the second red host 444a, the red emitter 446a, the first yellow-green host 442b, the second yellow-green host 444b, the yellow-green emitter 446b, the first green host 442c, the second green host 444c and the green emitter 446c in the first to third layers 440A to 440C, and the thicknesses of the first to third layers 440A to 440C can be identical to the corresponding materials, contents and the thickness with referring to FIGS. 3, 5 and 6.

The OLED D2 has a tandem structure of multiple emitting parts and at least one emitting part includes the first layer 440A of the red emitting material layer, the second layer 440B of the yellow-green emitting material layer and the third layer 440C of the green emitting material layer. The thicknesses of the first to third layers 440A, 440B and 440C are controlled so that the color temperature of the white light and the color gamut of the OLED D2 can be improved.

The contents and the energy levels of the hosts 442a, 444a, 442b, 444b, 442c and/or 444c within the first to third layer 440A, 440B and 440C can be controlled so that the emission area can be distributed uniformly within the entire area of the EML2 440. The degradations of the luminous materials within the EML2 440 and the charge transporting materials in the charge transport layers 420 and 460 caused by the interactions with the excitons generated at the particular area and/or the non-emissive quenching excitons can be prevented. Therefore, the OLED D2 with improved luminous lifespan as well as stable luminous efficiency can be fabricated.

### EXAMPLES

The following examples are not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### Example 1 (Ex. 1): Fabrication of OLED

An organic light emitting diode that includes a red emitting material layer, a yellow-green emitting material layer and a green emitting material layer each of which has a controlled thickness and includes a host with a controlled energy level, was fabricated. A glass substrate onto which ITO (1200 Å) was coated as a thin film was washed and ultrasonically cleaned by solvent such as isopropyl alcohol, acetone and dried at 100° C. oven. The substrate was transferred to a vacuum chamber for depositing emissive layer as the following order:

Hole injection layer (HIL, DNTDP (50 wt. %), MgF₂ (50 wt. %), 70 Å); first hole transport layer (HTL1, DNTDP, 1000 Å); a first electron blocking layer (EBL1, TCTA, 150 Å); first blue emitting material layer (B-EML1, MADN (97 wt. %), t-DABNA (3 wt. %), 200 Å); first electron transport layer (ETL1, ZADN, 200 Å); first N-type charge generation layer (N-CGL1, Bphen (98 wt. %), Li (2 wt. %), 150 Å); first P-type charge generation layer (P-CGL1, DNTPD (90 wt. %), P-type dopant (10 wt. %), 80 Å); second hole transport layer (HTL2, BPBPA, 50 Å); red emitting material layer (R-EML, Host (BPBPA of Compound RHH-1 in Chemical Formula 2 (HOMO: −5.50 eV, LUMO: −2.44 eV): Compound REH-1 in Chemical Formula 4 (HOMO: −5.57 eV, LUMO: −2.84 eV)=5:5 by weight ratio, 98 wt. %), Ir(piq)₂acac (2 wt. %), 130 Å); yellow-green emitting material layer (YG-EML, Host (GHH5 in Chemical Formula 10 (YGHH, HOMO: −5.63 eV, LUMO: −2.37 eV): YGEH below (HOMO: −5.72 eV, LUMO: −2.53 eV)=5:5 by weight ratio, 80 wt. %), PO-01 (20 wt. %), 140 Å); green emitting material layer (G-EML, GHH2 in Chemical Formula 10 (GHH, HOMO: −5.62 eV, LUMO: −2.35 eV): GEH below (HOMO: −6.0 eV, LUMO: −2.93 eV)=7:3 by weight ratio, 90 wt. %), Ir(ppy)₃ (10 wt. %), 190 Å); second electron transport layer (ETL2, ETL2 below (HOMO: −5.98 eV, LUMO: −3.06 eV), 180 Å); second N-type charge generation layer (N-CGL2, Bphen (98 wt. %), Li (2 wt. %), 240 Å); third hole transport layer (HTL3, DNTPD, 600 Å); second electron blocking layer (EBL2, TCTA, 150 Å); second blue emitting material layer (B-EML2, MADN (97 wt. %), t-DABNA (3 wt. %), 200 Å); third electron transport layer (ETL3, ZADN, 200 Å); electron injection layer (EIL, LiF, 15 Å); and cathode (Al, 1000 Å).

The fabricated OLED was encapsulated with glass and then transferred from the deposition chamber to a dry box in order to form a film. Then, the OLED was encapsulated with UV-cured epoxy resin and water getter. The structures of materials of hole injecting material, hole transporting material, emitting host, red dopant, yellow-green dopant, green dopant, electron transporting material and charge generating material are in the following:

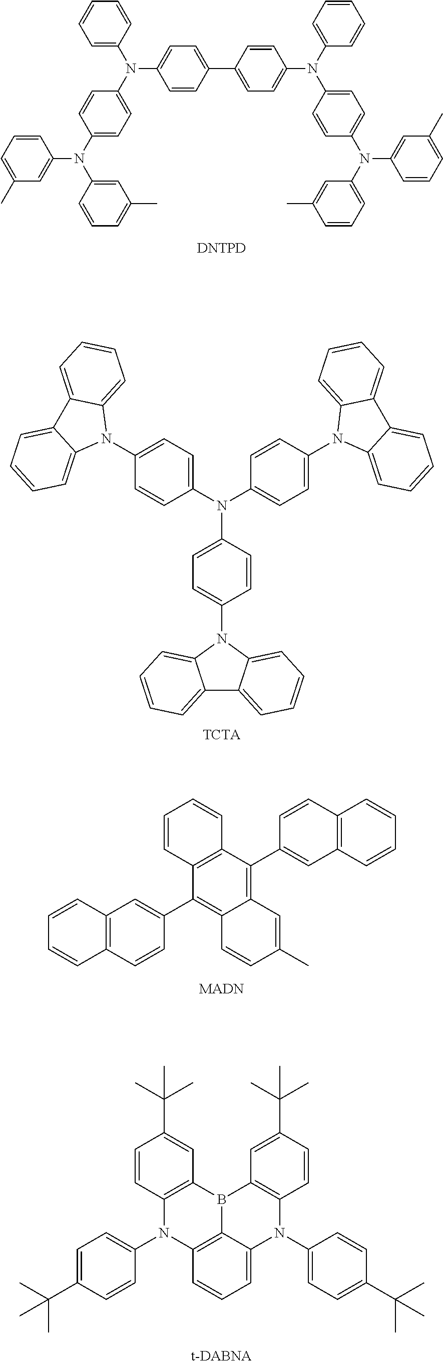

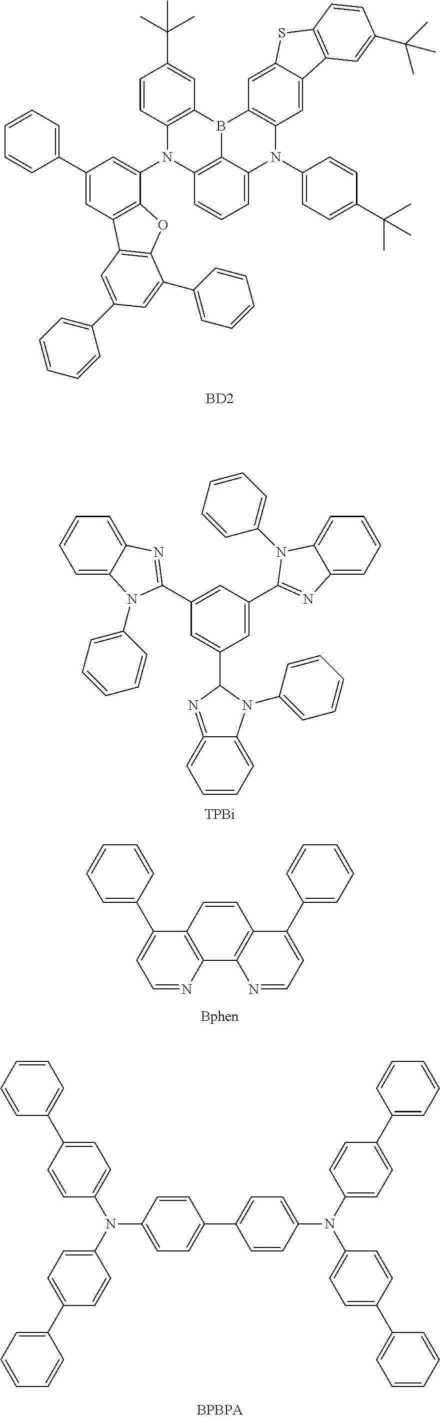

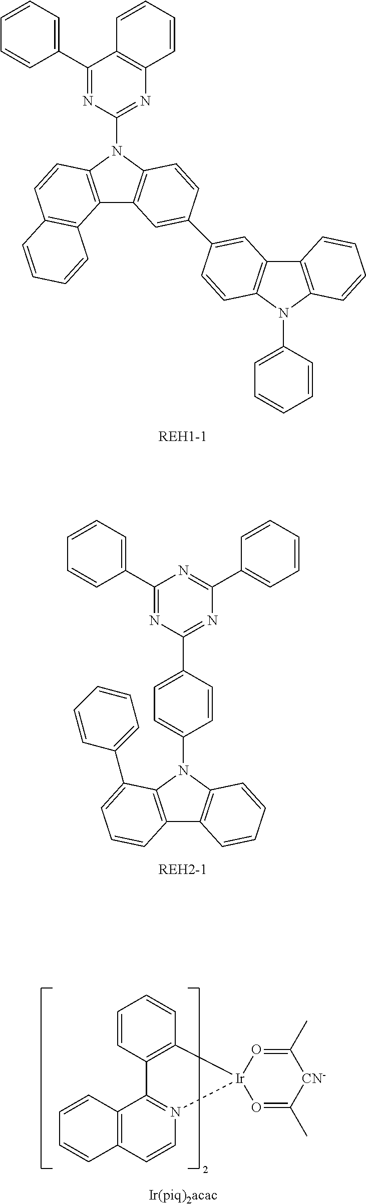

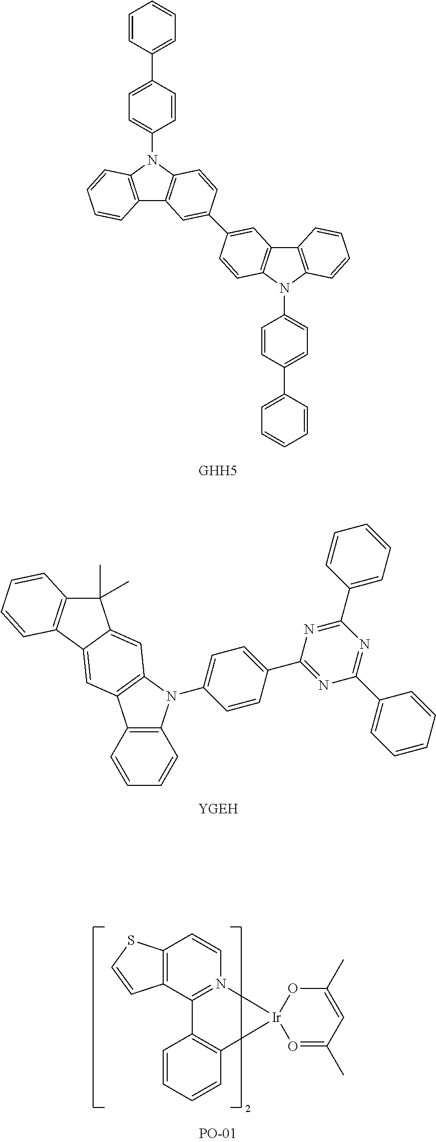

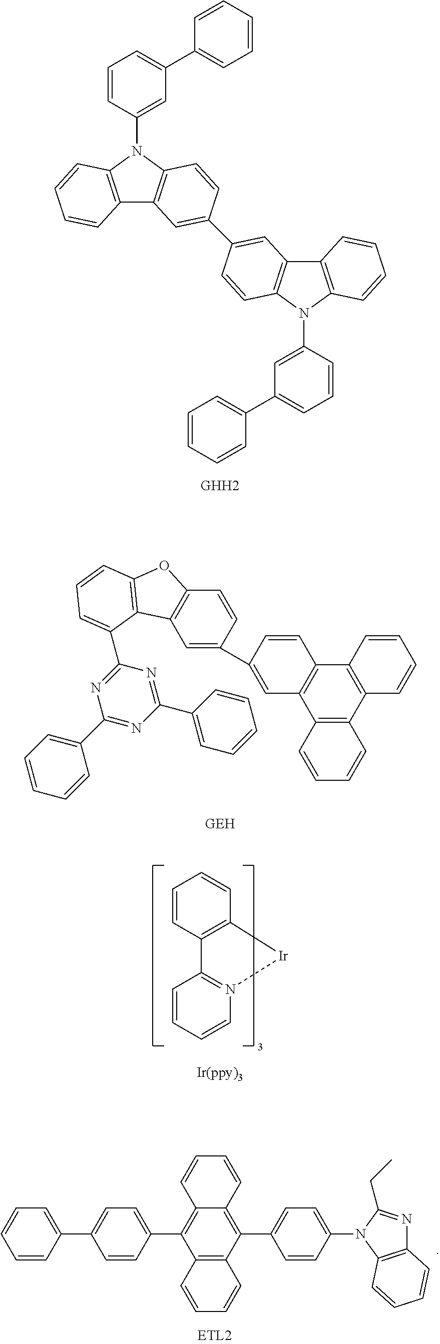

### Examples 2-3 (Ex. 2-3): Fabrication of OLEDs

An OLED was fabricated using the same procedure and the same material as Example 1, except that the mixing ratio of Compound RHH-1 and Compound REH-1 in the R-EML was modified to 4:6 by weight (Ex. 2) or to 3:7 by weight (Ex. 3) instead of 5:5 by weight.

### Example 4 (Ex. 4): Fabrication of OLEDs

An OLED was fabricated using the same procedure and the same material as Example 1, except that the mixing ratio of Compound RHH-1 and Compound REH-1 in the R-EML was modified to 4:6 by weight instead of 5:5 by weight, and the thickness of the R-EML, the YG-EML and the G-EML was modified to 150 Å, 100 Å, 250 Å, respectively.

### Comparative Example 1 (Ref. 1): Fabrication of OLED

An OLED was fabricated using the same procedure and the same material as Example 1, except that the thickness of the YG-EML and the G-EML was modified to 180 Å, 150 Å, respectively.

Table 1 below indicates the weight ratio between a P-type (hole type) host and N-type host (electron type host) in the R-EML, YG-EML and the G-EML, and the thickness of the R-EML, YG-EML and the G-EML

TABLE 1
Structure and Thickness of Emitting Material Layer

| | | |
|---|---|---|
| R-EML | YG-EML | G-EML |

| | |
|---|---|
| Sample | P-type host: N-type host by weight, thickness |

| | | | |
|---|---|---|---|
| Ref. 1 | 5:5, 130 Å | 5:5, 180 Å | 7:3, 150 Å |
| Ex. 1 | 5:5, 130 Å | 5:5, 140 Å | 7:3, 190 Å |
| Ex. 2 | 4:6, 130 Å | 5:5, 140 Å | 7:3_190 Å |
| Ex. 3 | 3:7, 130 Å | 5:5, 140 Å | 7:3, 190 Å |
| Ex. 4 | 4:6, 150 Å | 5:5, 100 Å | 7:3, 250 Å |

### Experimental Example 1: Measurement of Electro-Optical Properties of OLEDs

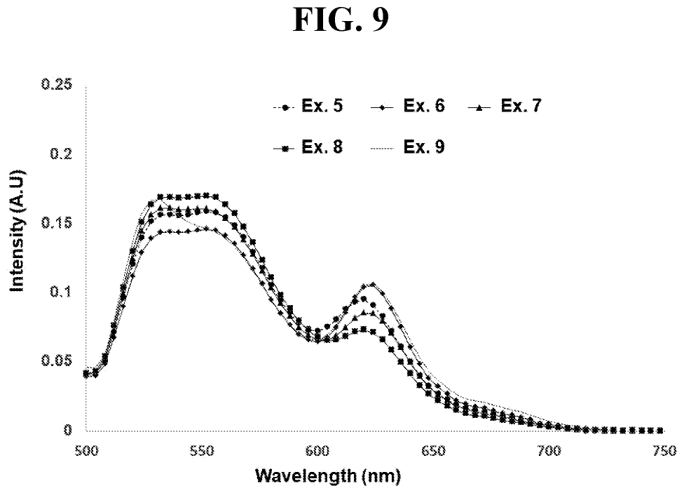

The luminous properties for each of the OLEDs, fabricated in Examples 1 to 4 and Comparative Example 1, were measured. Each of the OLEDs were connected to an external power source and then luminous properties for all the OLEDs were evaluated using a constant current source (KEITHLEY) and a photometer PR650 at room temperature. In particular, red light and green light current efficiency (cd/A), color coordinates (CIEx, CIEy) were measured at current density of 10 mA/cm², and luminous lifespan (T⁹⁵, relative value, %) of red light and green light, time period when the luminance was reduced to 95% level from the initial luminance, correlated color temperature (CCT) and color gamut (BT2020) of white light were measured at a current density of 40 mA/cm² and 40° C. In addition, electroluminescence (EL) intensity at green wavelength (528 nm), yellow-green wavelength (556 nm) and red wavelength (620 nm) for the OLEDs was measured. Measurement results are indicated in the following Tables 2 and 3 and FIG. 8.

TABLE 2
Luminous Properties of OLED

| | | | | | | | | | | Color |
|---|---|---|---|---|---|---|---|---|---|---|
| | Red | | | | Green | | | | W | Gamut |
| Sample | cd/A | CIEx | CIEy | T⁹⁵ (%) | cd/A | CIEx | CIEy | T⁹⁵ (%) | CCT | BT2020 |
| Ref. 1 | 8.51 | 0.680 | 0.319 | 100 | 26.45 | 0.265 | 0.677 | 100 | 7675 | 75.9 |
| Ex. 1 | 8.36 | 0.680 | 0.319 | 76 | 28.01 | 0.259 | 0.682 | 96 | 7876 | 76.1 |
| Ex. 2 | 8.84 | 0.682 | 0.318 | 86 | 27.05 | 0.256 | 0.683 | 100 | 8035 | 77.1 |
| Ex. 3 | 9.09 | 0.683 | 0.317 | 90 | 26.76 | 0.254 | 0.684 | 104 | 8070 | 77.6 |
| Ex. 4 | 9.06 | 0.684 | 0.316 | 71 | 28.19 | 0.244 | 0.693 | 83 | 8373 | 78.8 |

TABLE 3
EL Intensity in Wavelength Range of OLED

| Wavelength (nm) | Ref. 1 | Ex. 1 | Ex. 2 | Ex. 3 | Ex. 4 |
|---|---|---|---|---|---|
| 528 | 0.62 | 0.71 | 0.73 | 0.76 | 0.92 |
| 556 | 1.00 | 1.00 | 1.00 | 1.00 | 1.00 |
| 620 | 0.56 | 0.54 | 0.63 | 0.68 | 0.71 |

As indicated in Tables 2 and 3 and FIG. 8, compared to the OLED fabricated in Comparative Example 1 where the thickness of the YG-EML among the R-EMVL, the YG-EML and the G-EML was largest, in the OLEDs fabricated in Examples 1 to 4 where the thickness of the G-EML was larger than the thickness of the YG-EMVL, or the thicknesses of the R-EML and the G-EMVL was larger than the thickness of the YG-EMVL, CCT of the white was generally improved. As the relative thickness of the YG-EML decreases, color gamut was increased and the current efficiency of the green light and the red light was equivalent level or a little increased.

### Example 5 (Ex. 5): Fabrication of OLED

An OLED was fabricated using the same procedure and the same material as Example 4, except that the blue emitter BD2 instead of t-DABNA in the B-EML1 and B-EML2 was used.

### Example 6 (Ex. 6): Fabrication of OLED

An OLED was fabricated using the same procedure and the same material as Example 5, except that Compound REH2-1 (HOMO: −5.75 eV, LUMO: −3.01 eV) instead of Compound REH1-1 in the R-EML was used as the second red host.

### Examples 7-8 (Ex. 7-8): Fabrication of OLEDs

An OLED was fabricated using the same procedure and the same material as Example 6, except that the mixing ratio of Compound RHH-1 and Compound REH-2 in the R-EML was modified to 5:5 by weight (Ex. 7) or to 6:4 by weight (Ex. 8) instead of 4:6 by weight.

### Example 9 (Ex. 9): Fabrication of OLED

An OLED was fabricated using the same procedure and the same material as Example 6, except that the thickness of the G-EML was modified to 300 Å.

Table 4 below indicates the weight ratio between a P-type (hole type) host and N-type host (electron type host) in the R-EML, YG-EML and the G-EML, and the thickness of the R-EML, YG-EML and the G-EML

TABLE 4
Structure and Thickness of Emitting Material Layer

| | | |
|---|---|---|
| R-EML | YG-EML | G-EML |

| | |
|---|---|
| Sample | P-type host: N-type host by weight, thickness |

| | | | |
|---|---|---|---|
| Ref. 1 | 5:5, 130 Å | 5:5, 180 Å | 7:3, 150 Å |
| Ex. 5 | 4:6, 150 Å | 5:5, 100 Å | 7:3, 250 Å |
| Ex. 6 | 4:6, 150 Å | 5:5, 100 Å | 7:3_250 Å |
| Ex. 7 | 5:5, 130 Å | 5:5, 100 Å | 7:3, 250 Å |
| Ex. 8 | 6:4, 150 Å | 5:5, 100 Å | 7:3, 250 Å |
| Ex. 9 | 4:6, 150 Å | 5:5 100 Å | 7:3, 300 Å |

### Experimental Example 2: Measurement of Electro-Optical Properties of OLEDs

The luminous properties and EL intensities for each of the OLEDs, fabricated in Examples 5 to 9 and Comparative Example 1, were measured as Experimental Example 2. Measurement results are indicated in the following Tables 5 and 6 and FIG. 9.

TABLE 5
Luminous Properties of OLED

| | | | | | | | | | | Color |
|---|---|---|---|---|---|---|---|---|---|---|
| | Red | | | | Green | | | | W | Gamut |
| Sample | cd/A | CIEx | CIEy | T⁹⁵ (%) | cd/A | CIEx | CIEy | T⁹⁵ (%) | CCT | BT2020 |
| Ref. 1 | 8.51 | 0.680 | 0.319 | 100 | 26.45 | 0.265 | 0.677 | 100 | 7675 | 75.9 |
| Ex. 5 | 7.75 | 0.681 | 0.317 | 76 | 28.59 | 0.244 | 0.698 | 83 | 10059 | 79.6 |
| Ex. 6 | 8.16 | 0.685 | 0.314 | 105 | 26.33 | 0.243 | 0.697 | 104 | 10701 | 81.1 |
| Ex. 7 | 7.07 | 0.682 | 0.316 | 100 | 29.08 | 0.243 | 0.700 | 91 | 10251 | 80.0 |
| Ex. 8 | 6.36 | 0.679 | 0.319 | 81 | 30.614 | 0.244 | 0.700 | 87 | 10093 | 78.7 |
| Ex. 9 | 8.4 | 0.686 | 0.313 | 105 | 28.836 | 0.233 | 0.703 | 100 | 12014 | 81.7 |

TABLE 6
EL Intensity in Wavelength Range of OLED

| Wavelength (nm) | Ex. 5 | Ex. 6 | Ex. 7 | Ex. 8 | Ex. 9 |
|---|---|---|---|---|---|
| 528 | 0.96 | 0.96 | 0.99 | 0.97 | 1.16 |
| 556 | 1.00 | 1.00 | 1.00 | 1.00 | 1.00 |
| 620 | 0.60 | 0.72 | 0.54 | 0.43 | 0.73 |

As indicated in Tables 5 and 6 and FIG. 9, compared to the OLED fabricated in Comparative Example 1 where the thickness of the YG-EML among the R-EMVL, the YG-EML and the G-EML was largest, in the OLEDs fabricated in Examples 5 to 9 where the thickness of the G-EML was larger than the thickness of the YG-EML, CCT of the white was generally improved. Particularly, in the OLEDs fabricated in Examples 6 to 9 where the red N-type host with relatively lower LUMO energy level was used, the color gamut and luminous lifespan was improved, which indicates that red light and green light was separately emitted as the emission distribution enlarges. In addition, red light emission peak value compared to the yellow-green light emission peak was increased. In particular, in the OLED fabricated in Example 9 where the thickness of the G-EML compared to the thickness of the YG-EML was further increased, the EL intensity of the green light is further increased, the current efficiency of the red light and the green light, white light color temperature and color gamut was further improved.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. An organic light emitting diode, comprising:
a first electrode;
a second electrode facing the first electrode; and
an emissive layer disposed between the first and second electrode, and comprising at least one emitting part,
wherein the at least one emitting part comprises:
a red emitting material layer comprising a first red host;
a yellow-green emitting material layer disposed between the red emitting material layer and the second electrode, and comprising a first yellow-green host; and
a green emitting material layer disposed between the yellow-green emitting material layer and the second electrode, and comprising a first green host,
wherein the green emitting material layer has a thickness larger than a thickness of the yellow-green emitting material layer, and
optionally, wherein the thickness of the green emitting material layer is larger than a thickness of the red emitting material layer.

2. The organic light emitting diode of claim 1, wherein the red emitting material layer has a thickness from about 100 Å and about 300 Å, the yellow-green emitting material layer has a thickness from about 50 Å and about 200 Å, the green emitting material layer has a thickness from about 100 Å and about 400 Å,
wherein the green emitting material layer has a thickness larger than a thickness of the yellow-green emitting material layer, and
wherein the thickness of the green emitting material layer is larger than a thickness of the red emitting material layer.

3. The organic light emitting diode of claim 1, wherein the first red host is a compound according to Chemical Formula 1 or Chemical Formula 2,
wherein the first yellow-green host and the first green host are each independently a compound according to Chemical Formula 9, or Chemical Formula 10: 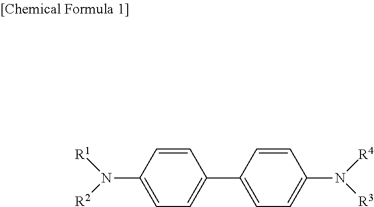
wherein, in Chemical Formula 1,
each of R¹, R², R³ and R⁴ is independently an unsubstituted or substituted C₆-C₃₀ aryl group or an unsubstituted or substituted C₃-C₃₀ hetero aryl group; 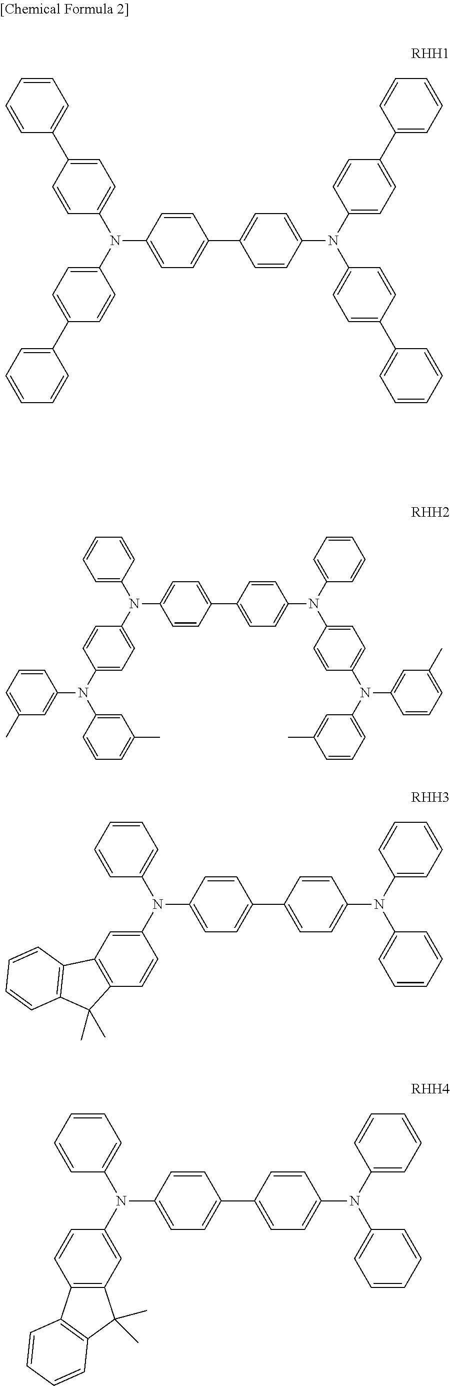 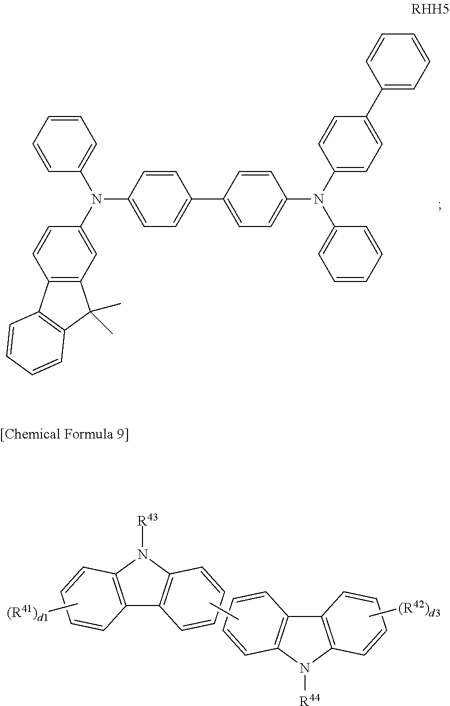
wherein, in Chemical Formula 9,
each of R⁴¹, R⁴², R⁴³ and R⁴⁴ is independently an unsubstituted or substituted C₆-C₃₀ aryl group or an unsubstituted or substituted C₃-C₃₀ hetero aryl group, where each R⁴³ is identical to or different from each other when d1 is 2, 3 or 4 and each R⁴² is identical to or different from each other when d3 is 2, 3 or 4, or, optionally, each of the unsubstituted or substituted C₆-C₃₀ aryl group and the unsubstituted or substituted C₃-C₃₀ hetero aryl independently forms a spiro structure with an unsubstituted or substituted C₆-C₂₀ aromatic ring or an unsubstituted or substituted C₃-C₂₀ hetero aromatic ring; and
each of d1 and d2 is independently 0, 1, 2, 3 or 4;

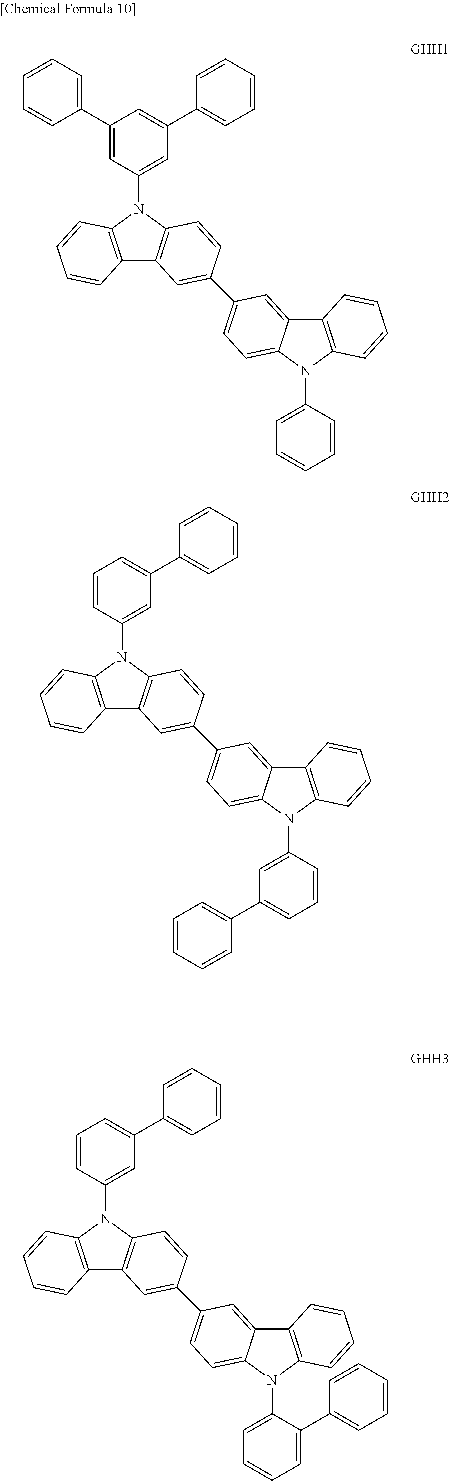 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

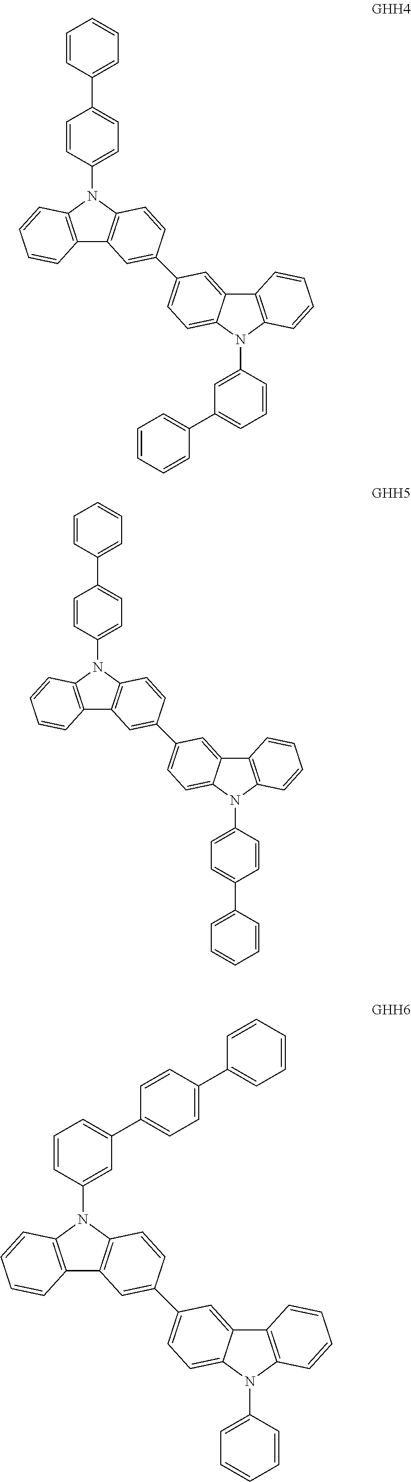 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-c3cccc(-n4c5ccccc5c5cc(-c6ccc7c(c6)c6ccccc6n7-c6ccccc6)ccc54)c3)cc2)cc1]

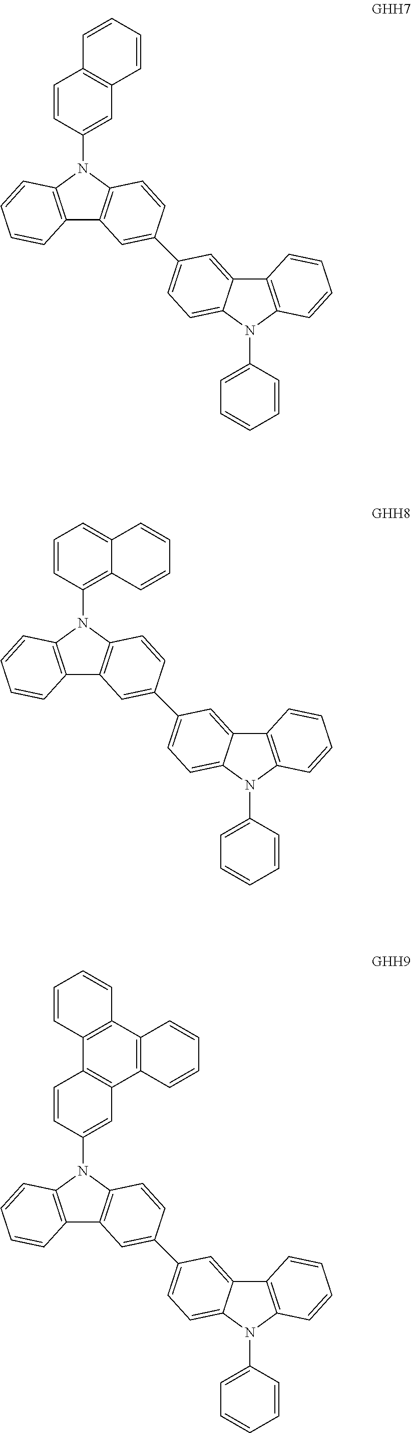 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

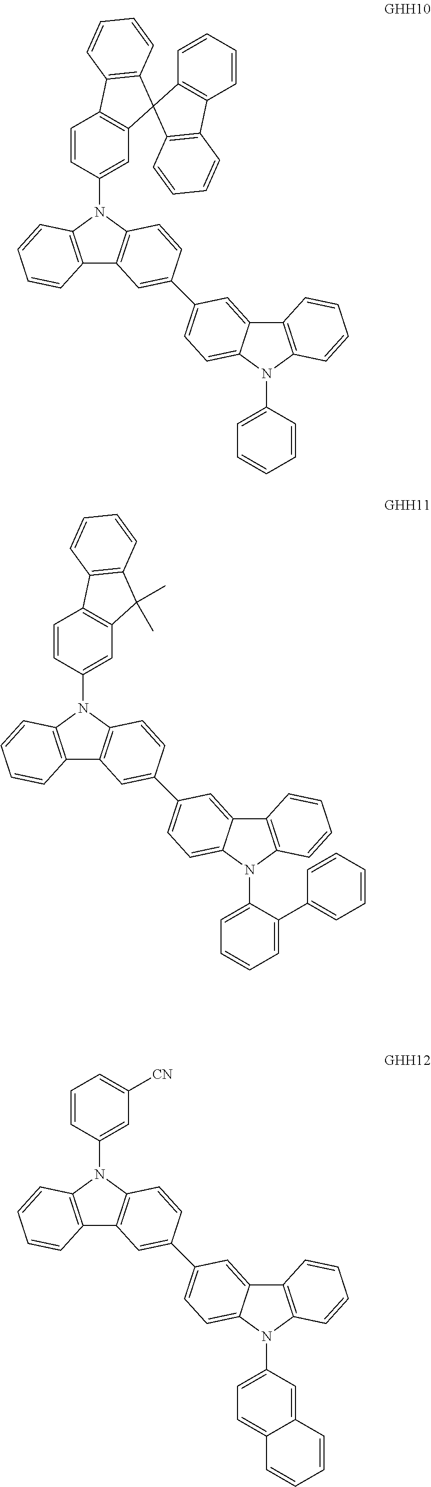 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

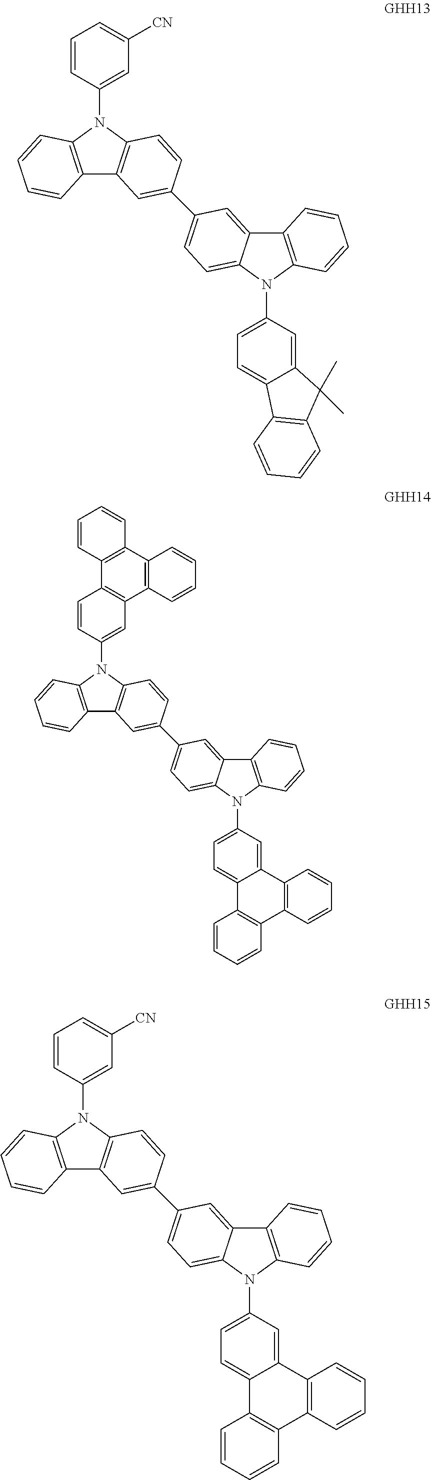 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21 ; N#Cc1cccc(-n2c3ccccc3c3cc(-c4ccc5c(c4)c4ccccc4n5-c4ccc5c6ccccc6c6ccccc6c5c4)ccc32)c1]

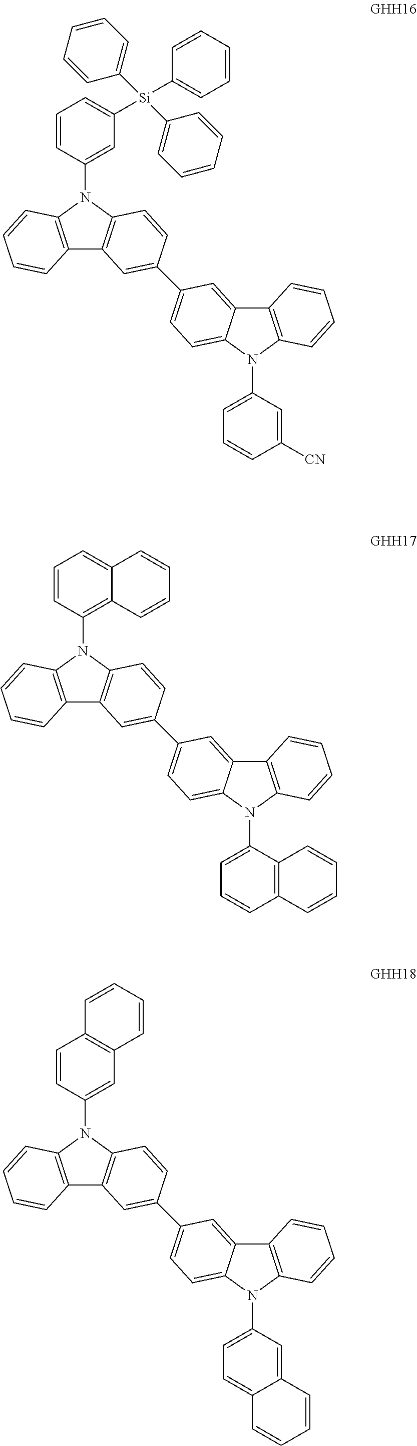 [SMILES: N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1 ; c1ccc2cc(-n3c4ccccc4c4cc(-c5ccc6c(c5)c5ccccc5n6-c5ccc6ccccc6c5)ccc43)ccc2c1]

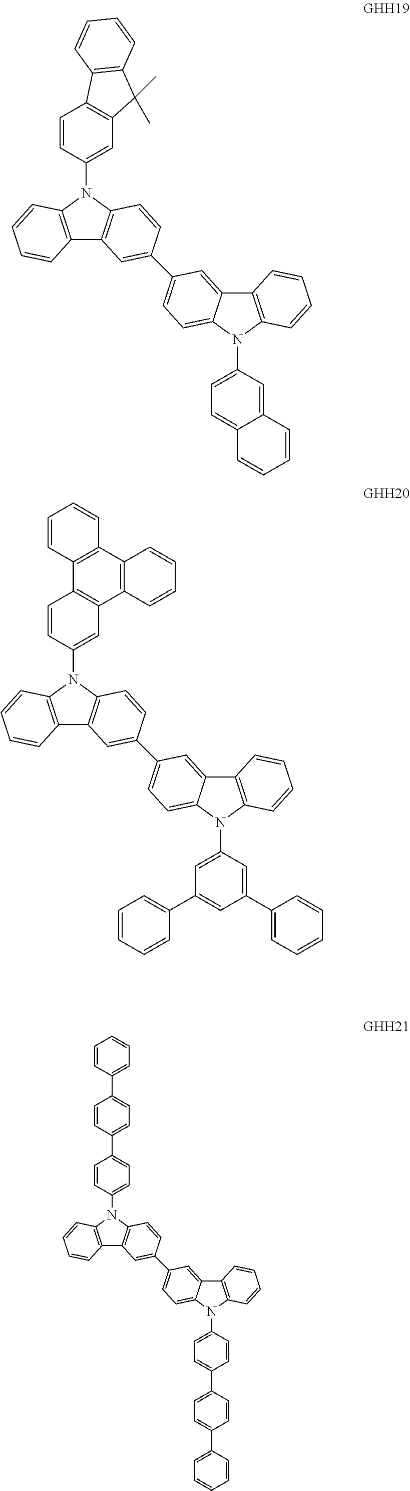 [SMILES: CC1(C)c2ccccc2-c2ccc(-n3c4ccccc4c4cc(-c5ccc6c(c5)c5ccccc5n6-c5ccc6ccccc6c5)ccc43)cc21 ; c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1 ; c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1]

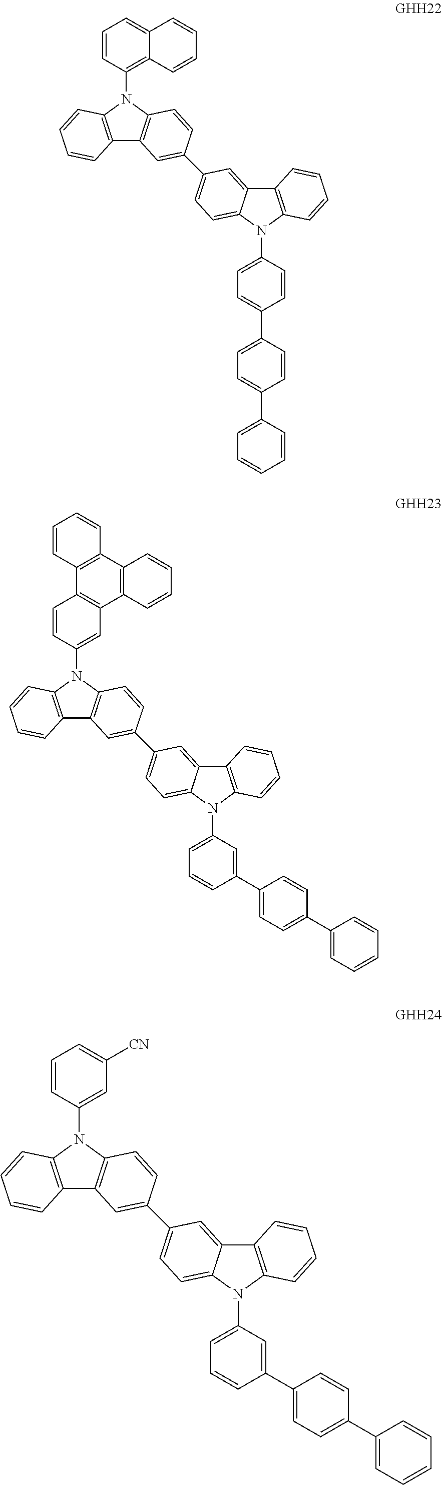 [SMILES: c1ccc(-c2ccc(-c3ccc(-n4c5ccccc5c5cc(-c6ccc7c(c6)c6ccccc6n7-c6cccc7ccccc67)ccc54)cc3)cc2)cc1 ; c1ccc(-c2ccc(-c3cccc(-n4c5ccccc5c5cc(-c6ccc7c(c6)c6ccccc6n7-c6ccc7c8ccccc8c8ccccc8c7c6)ccc54)c3)cc2)cc1 ; N#Cc1cccc(-n2c3ccccc3c3cc(-c4ccc5c(c4)c4ccccc4n5-c4cccc(-c5ccc(-c6ccccc6)cc5)c4)ccc32)c1]

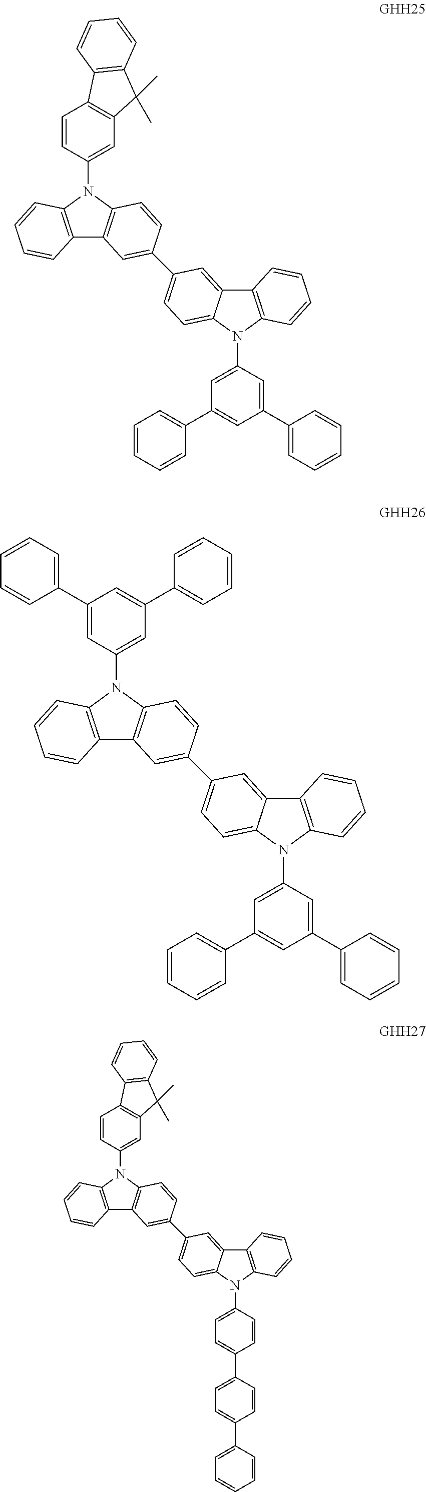 [SMILES: CC1(C)c2ccccc2-c2ccc(-n3c4ccccc4c4cc(-c5ccc6c(c5)c5ccccc5n6-c5cc(-c6ccccc6)cc(-c6ccccc6)c5)ccc43)cc21 ; c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1 ; CC1(C)c2ccccc2-c2ccc(-n3c4ccccc4c4cc(-c5ccc6c(c5)c5ccccc5n6-c5ccc(-c6ccc(-c7ccccc7)cc6)cc5)ccc43)cc21]

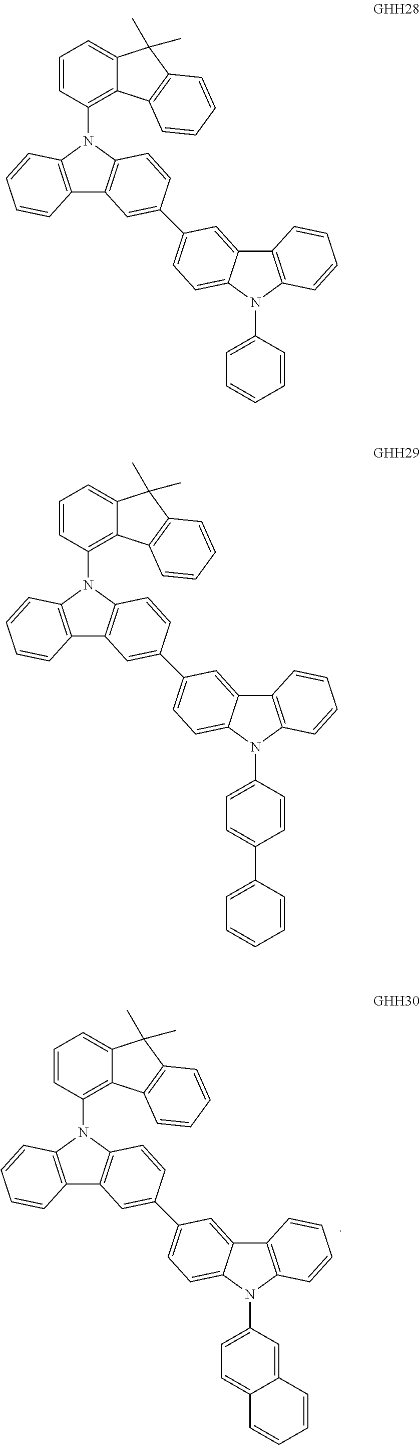 [SMILES: CC1(C)c2ccccc2-c2c(-n3c4ccccc4c4cc(-c5ccc6c(c5)c5ccccc5n6-c5ccccc5)ccc43)cccc21 ; CC1(C)c2ccccc2-c2c(-n3c4ccccc4c4cc(-c5ccc6c(c5)c5ccccc5n6-c5ccc(-c6ccccc6)cc5)ccc43)cccc21 ; CC1(C)c2ccccc2-c2c(-n3c4ccccc4c4cc(-c5ccc6c(c5)c5ccccc5n6-c5ccc6ccccc6c5)ccc43)cccc21]

4. The organic light emitting diode of claim 1, wherein the red emitting material layer further comprises a second red host selected from a compound according to Chemical Formula 3, Chemical Formula 4, Chemical Formula 5 or Chemical Formula 6: 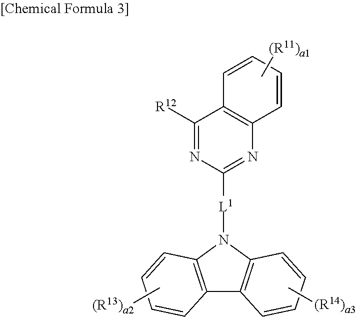
wherein, in Chemical Formula 3,
R¹¹ is an unsubstituted or substituted C₁-C₂₀ alkyl group, an unsubstituted or substituted C₆-C₃₀ aryl group or an unsubstituted or substituted C₃-C₃₀ hetero aryl group, where each R¹¹ is identical to or different from each other when a1 is 2, 3 or 4;
R¹² is hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₆-C₃₀ aryl group or an unsubstituted or substituted C₃-C₃₀ hetero aryl group, where each R¹² is identical to or different from each other when a2 is 2, 3 or 4, each R¹³ is identical to or different from each other when a3 is 2, 3 or 4, or
optionally,
two adjacent R¹³ when a2 is 2, 3 or 4, and/or
two adjacent R¹⁴ when a3 is 2, 3 or 4 can be further linked together to form an unsubstituted or substituted C₆-C₂₀ aromatic ring; and
each of a1, a2 and a3 is independently 0, 1, 2, 3 or 4, where at least one of a2 and a3 is not 0; 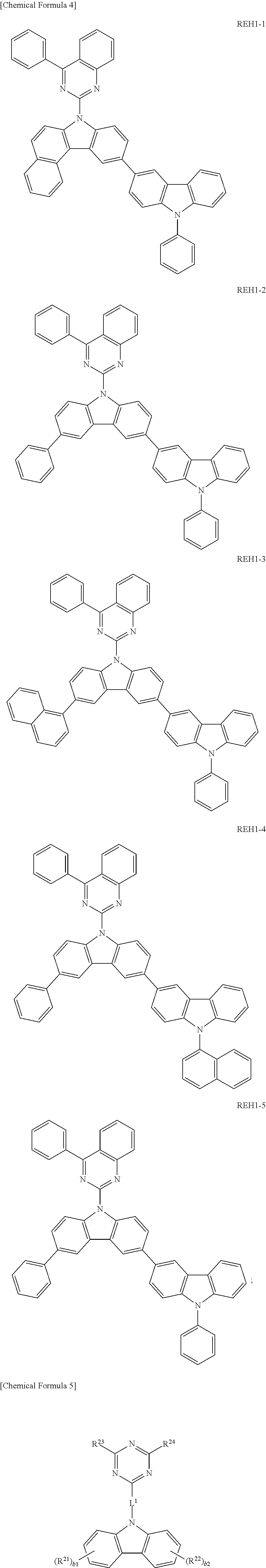
wherein, in Chemical Formula 5,
each of R²¹ and R²² is independently an unsubstituted or substituted C₁-C₂₀ alkyl group, an unsubstituted or substituted C₆-C₃₀ aryl group or an unsubstituted or substituted C₃-C₃₀ hetero aryl group, where at least one of R²¹ and R²² includes an unsubstituted or substituted carbazolyl moiety, each R²¹ is identical to or different from each other when b1 is 2, 3 or 4 and each R²² is identical to or different from each other when b2 is 2, 3 or 4;
each of R²³ and R²⁴ is independently an unsubstituted or substituted C₆-C₃₀ aryl group; L¹ is a single bond, an unsubstituted or substituted C₆-C₃₀ arylene group or an unsubstituted or substituted C₃-C₃₀ hetero arylene group; and
each of b1 and b2 is independently 0, 1, 2, 3 or 4;

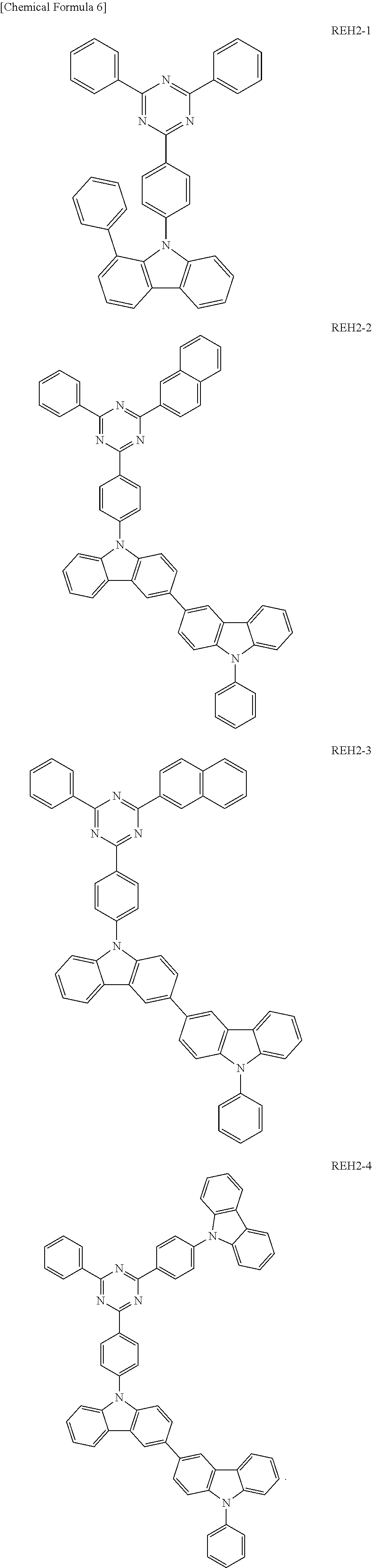

5. The organic light emitting diode of claim 1, wherein the red emitting material layer further comprises a second red host, wherein the second red host has an electron mobility larger than an electron mobility of the first red host, wherein the second red host has a lowest unoccupied molecular orbital (LUMO) energy level in a range between about −2.6 eV and about −3.2 eV, and optionally, wherein a content of the second red host is greater than a content of the first red host in the red emitting material layer.

6. The organic light emitting diode of claim 1, wherein the green emitting material layer further comprises a second green host, wherein the second green host has an electron mobility larger than an electron mobility of the first green host, and wherein a content of the first green host is greater than a content of the second green host in the green emitting material layer.

7. The organic light emitting diode of claim 1, wherein the green emitting material layer further comprises a second green host, wherein the second green host has an electron mobility larger than an electron mobility of the first green host, and wherein the second green host has a HOMO energy level in a range between about −5.4 eV and about −5.9 eV.

8. The organic light emitting diode of claim 1, wherein the red emitting material layer further comprises a second red host, the yellow-green emitting material layer further comprises a second yellow-green host and the green emitting material layer further comprises a second green host,
wherein the second red host has an electron mobility larger than an electron mobility of the first red host, the second yellow-green host has an electron mobility larger than an electron mobility of the first yellow-green host and the second green host has an electron mobility larger than an electron mobility of the first green host, and
wherein the second red host has a lowest unoccupied molecular orbital (LUMO) energy level lower than a lowest unoccupied molecular orbital (LUMO) energy level of at least one of the second yellow-green host and the second green host.

9. The organic light emitting diode of claim 1, wherein the emissive layer comprises:
a first emitting part;
a second emitting part disposed between the first emitting part and the second electrode; and
a first charge generation layer disposed between the first emitting part and the second emitting part, and
wherein one of the first emitting part and the second emitting part comprises the red emitting material layer, the yellow-green emitting material layer and the green emitting material layer.

10. The organic light emitting diode of claim 9, wherein the emissive layer further comprises:
a third emitting part disposed between the second emitting part and the second electrode; and
a second charge generation layer disposed between the second emitting part and the third emitting part.

11. An organic light emitting diode, comprising:
a first electrode;
a second electrode facing the first electrode; and
an emissive layer disposed between the first electrode and the second electrode,
wherein the emissive layer comprises:
a first emitting part;
a second emitting part disposed between the first emitting part and the second electrode; and
a first charge generation layer disposed between the first emitting part and the second emitting part,
wherein one of the first emitting part and the second emitting part comprises a first blue emitting material layer, and
wherein another of the first emitting part and the second emitting part comprises:
a red emitting material layer comprising a first red host;
a yellow-green emitting material layer disposed between the red emitting material layer and the second electrode, and comprising a first yellow-green host;
a green emitting material layer disposed between the yellow-green emitting material layer and the second electrode, and comprising a first green host,
wherein each of the red emitting material layer and the green emitting material layer has a thickness larger than a thickness of the yellow-green emitting material layer; and
optionally, wherein the thickness of the green emitting material layer is larger than the thickness of the red emitting material layer.

12. The organic light emitting diode of claim 11, wherein the red emitting material layer has a thickness between about 100 Å and about 300 Å, the yellow-green emitting material layer has a thickness between about 50 Å and about 200 Å, the green emitting material layer has a thickness between about 100 Å and about 400 Å,
wherein the green emitting material layer has the thickness larger than the thickness of the yellow-green emitting material layer, and
wherein the thickness of the green emitting material layer is larger than the thickness of the red emitting material layer.

13. The organic light emitting diode of claim 11, wherein the first red host is a compound according to Chemical Formula 1 or Chemical Formula 2, wherein the first yellow-green host and the first green host are each independently a compound according to Chemical Formula 9, or Chemical Formula 10: 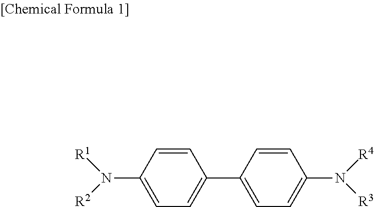
wherein, in Chemical Formula 1,
each of R¹, R², R³ and R⁴ is independently an unsubstituted or substituted C₆-C₃₀ aryl group or an unsubstituted or substituted C₃-C₃₀ hetero aryl group; 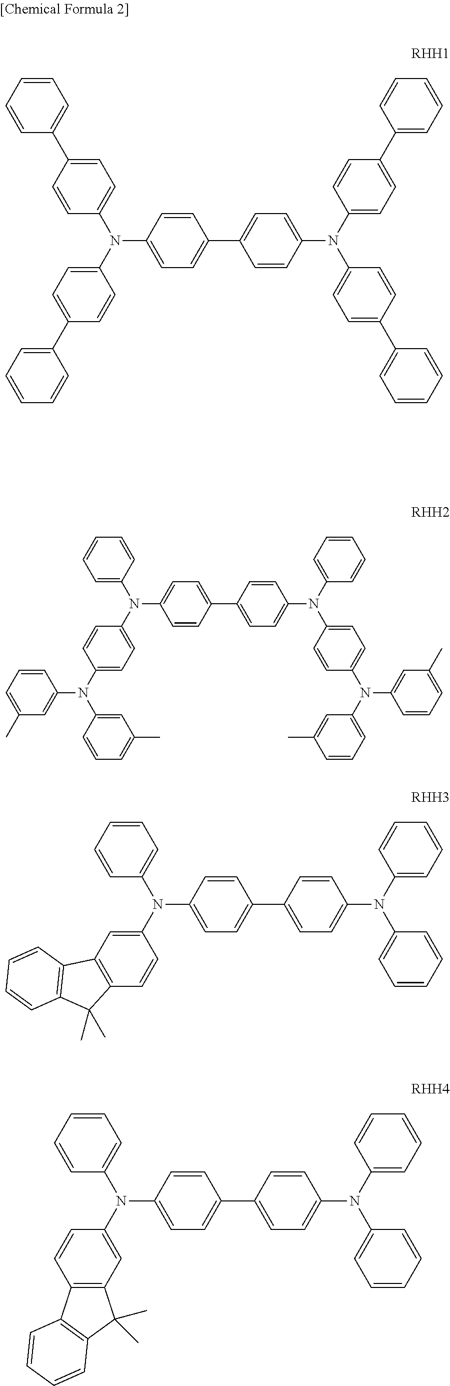 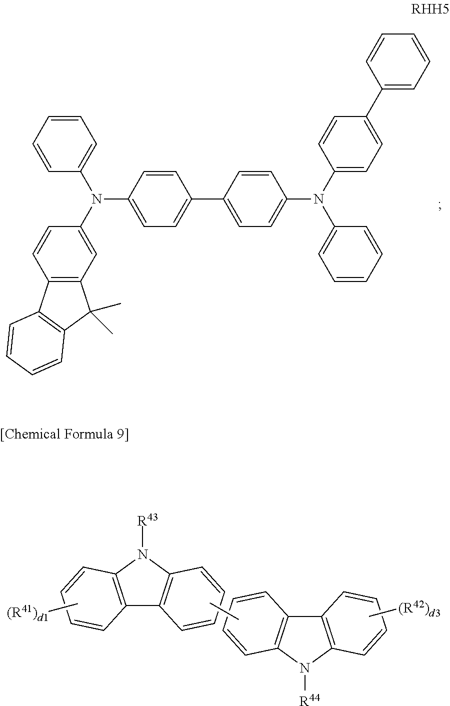
wherein, in Chemical Formula 9,
each of R⁴¹, R⁴², R⁴³ and R⁴⁴ is independently an unsubstituted or substituted C₆-C₃₀ aryl group or an unsubstituted or substituted C₃-C₃₀ hetero aryl group, where each R⁴³ is identical to or different from each other when d1 is 2, 3 or 4 and each R⁴² is identical to or different from each other when d3 is 2, 3 or 4, or, optionally, each of the unsubstituted or substituted C₆-C₃₀ aryl group and the unsubstituted or substituted C₃-C₃₀ hetero aryl independently forms a spiro structure with an unsubstituted or substituted C₆-C₂₀ aromatic ring or an unsubstituted or substituted C₃-C₂₀ hetero aromatic ring; and
each of d1 and d2 is independently 0, 1, 2, 3 or 4;

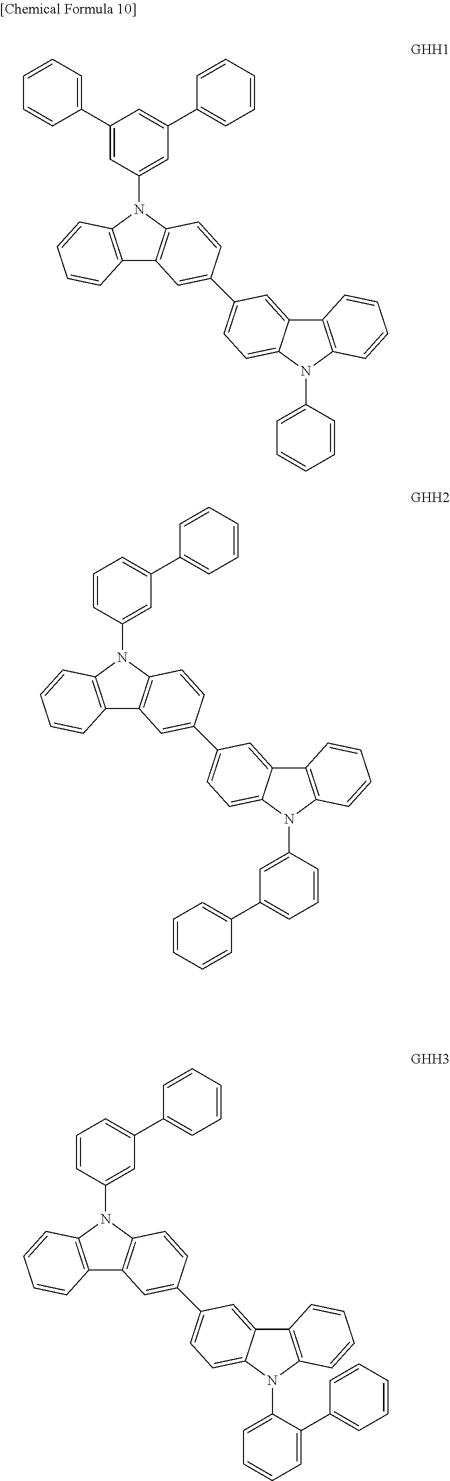 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

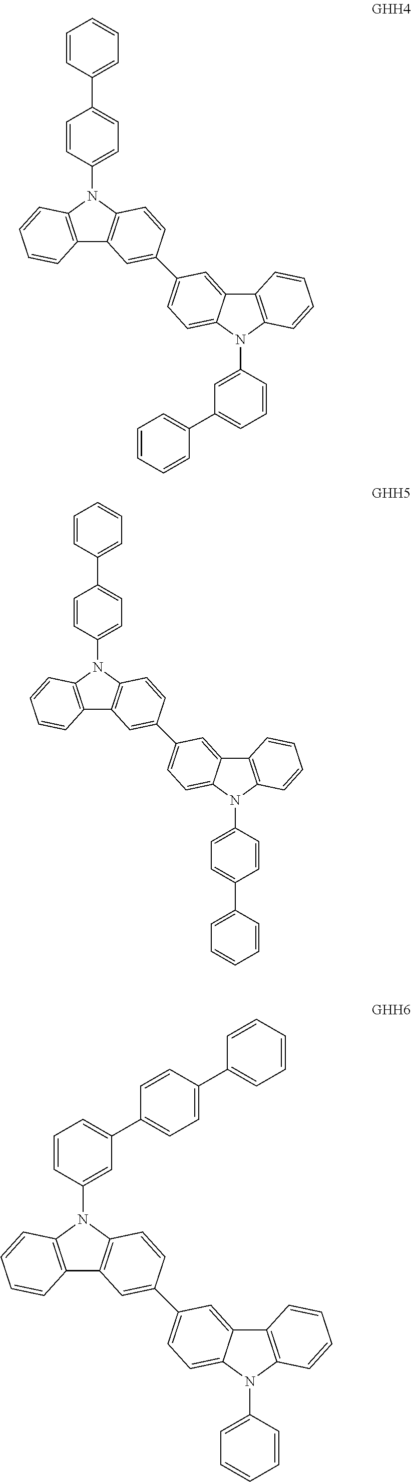 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-c3cccc(-n4c5ccccc5c5cc(-c6ccc7c(c6)c6ccccc6n7-c6ccccc6)ccc54)c3)cc2)cc1]

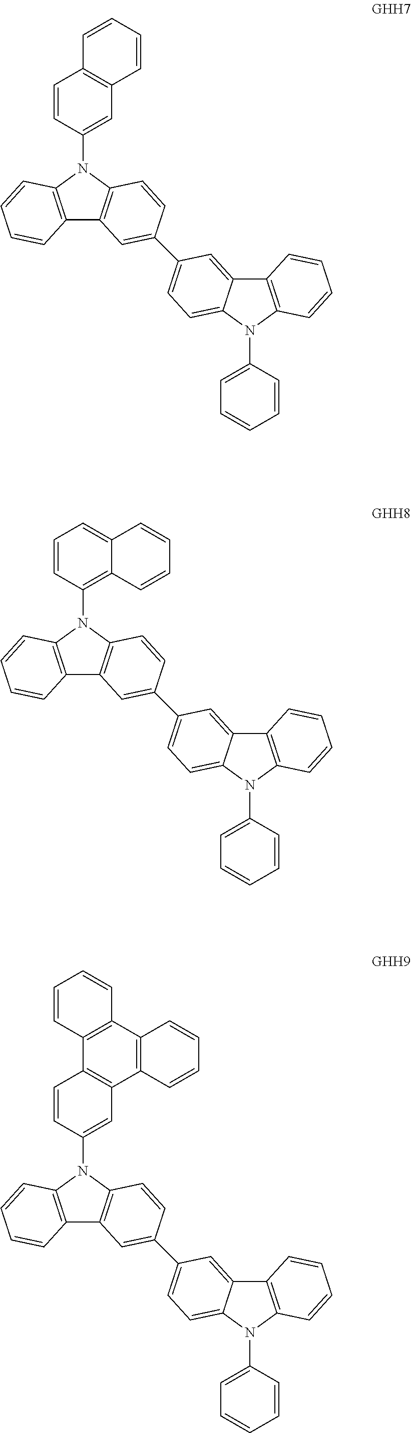 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

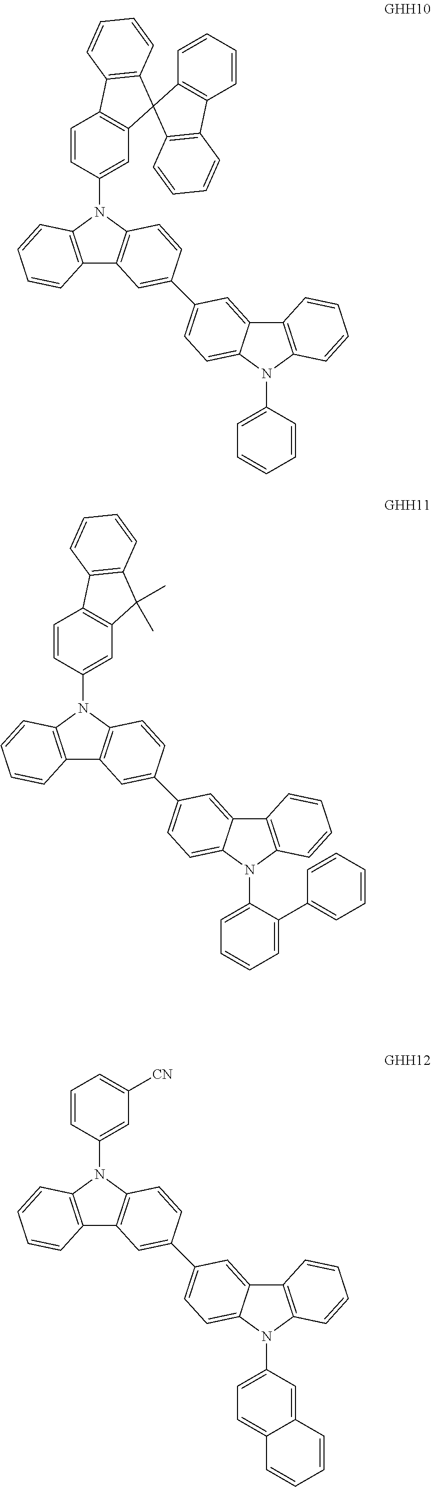 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

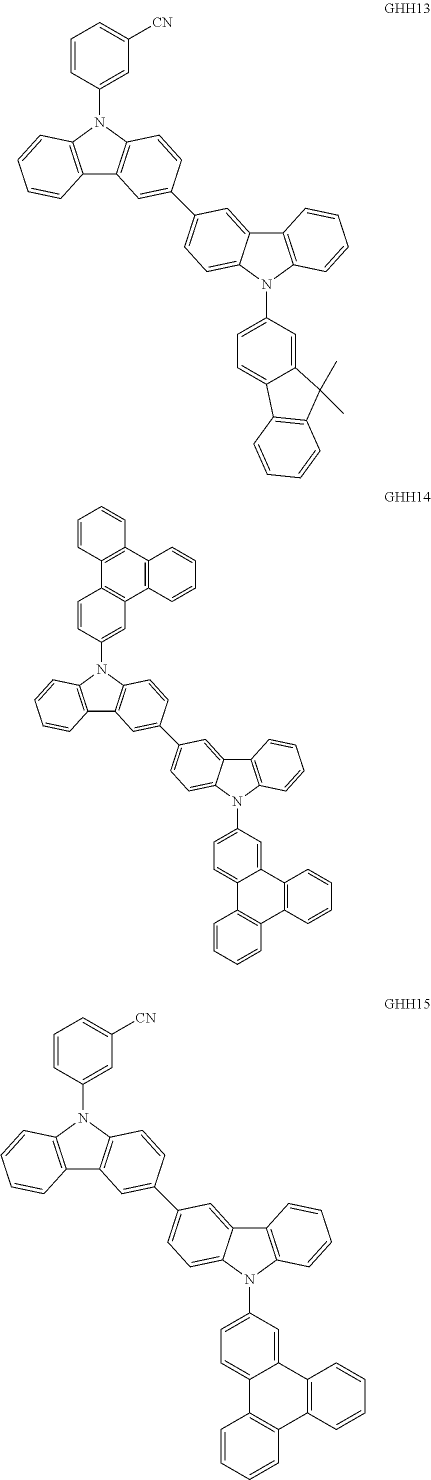 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21 ; N#Cc1cccc(-n2c3ccccc3c3cc(-c4ccc5c(c4)c4ccccc4n5-c4ccc5c6ccccc6c6ccccc6c5c4)ccc32)c1]

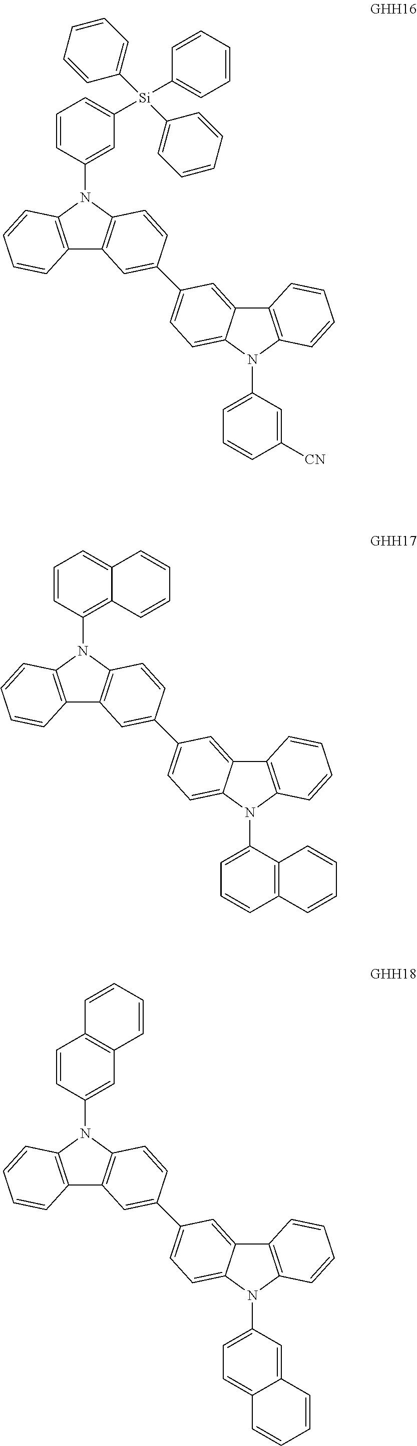 [SMILES: N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1 ; c1ccc2cc(-n3c4ccccc4c4cc(-c5ccc6c(c5)c5ccccc5n6-c5ccc6ccccc6c5)ccc43)ccc2c1]

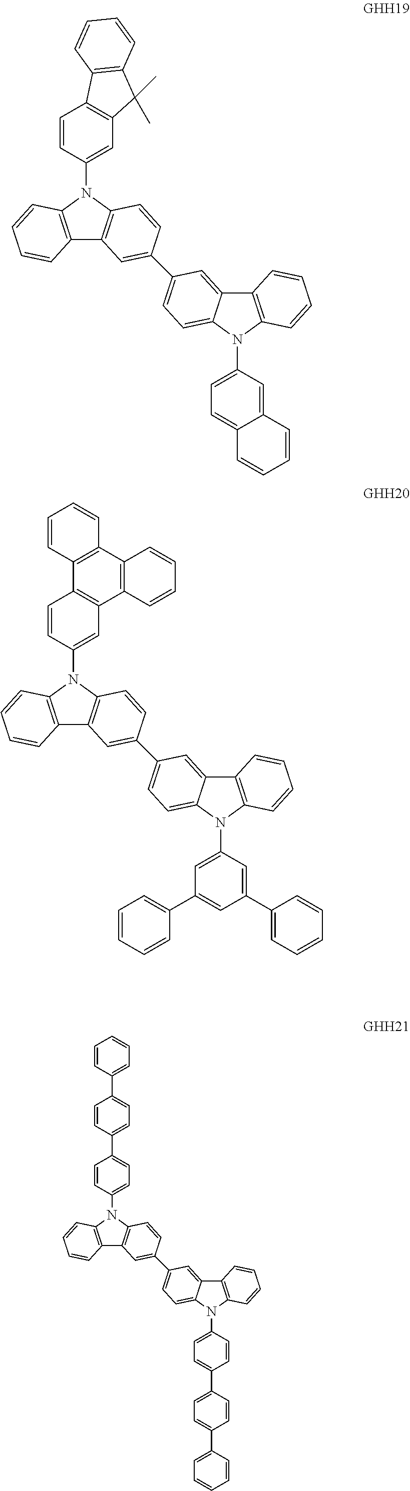 [SMILES: CC1(C)c2ccccc2-c2ccc(-n3c4ccccc4c4cc(-c5ccc6c(c5)c5ccccc5n6-c5ccc6ccccc6c5)ccc43)cc21 ; c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1 ; c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1]

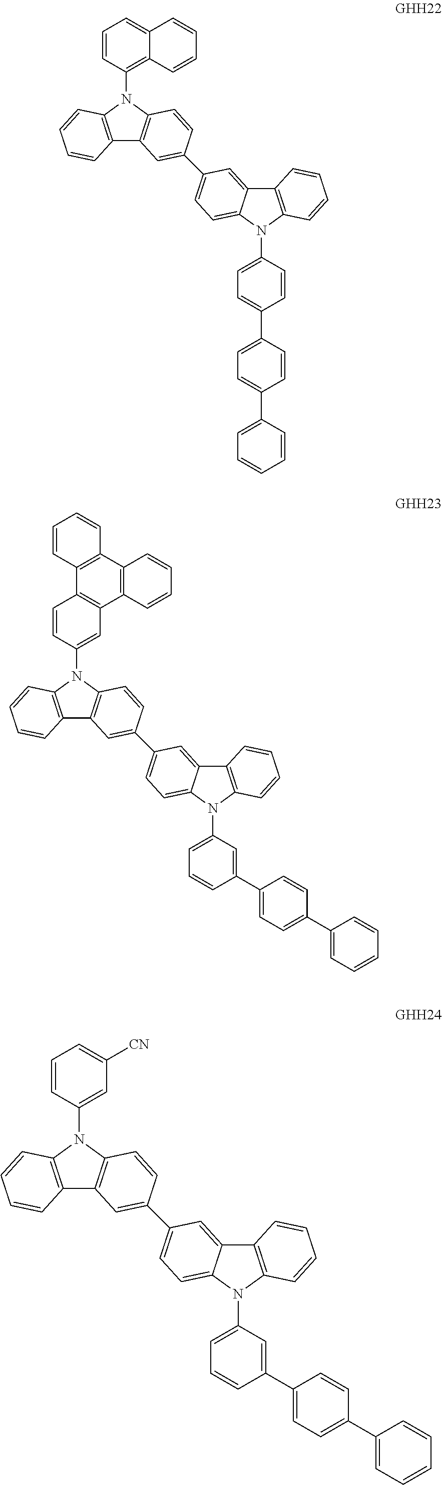 [SMILES: c1ccc(-c2ccc(-c3ccc(-n4c5ccccc5c5cc(-c6ccc7c(c6)c6ccccc6n7-c6cccc7ccccc67)ccc54)cc3)cc2)cc1 ; c1ccc(-c2ccc(-c3cccc(-n4c5ccccc5c5cc(-c6ccc7c(c6)c6ccccc6n7-c6ccc7c8ccccc8c8ccccc8c7c6)ccc54)c3)cc2)cc1 ; N#Cc1cccc(-n2c3ccccc3c3cc(-c4ccc5c(c4)c4ccccc4n5-c4cccc(-c5ccc(-c6ccccc6)cc5)c4)ccc32)c1]

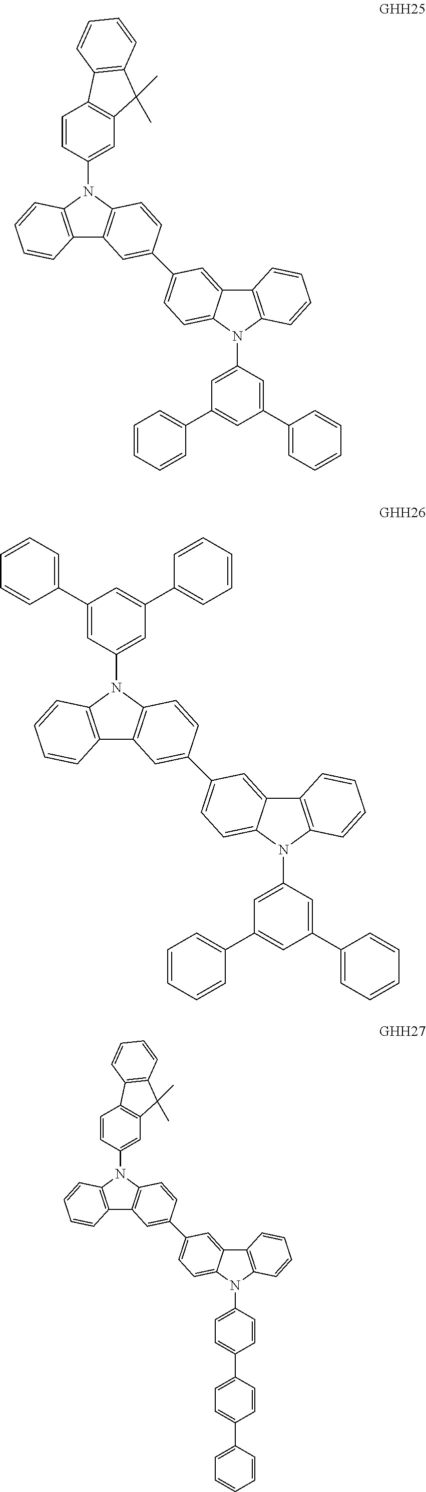 [SMILES: CC1(C)c2ccccc2-c2ccc(-n3c4ccccc4c4cc(-c5ccc6c(c5)c5ccccc5n6-c5cc(-c6ccccc6)cc(-c6ccccc6)c5)ccc43)cc21 ; c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1 ; CC1(C)c2ccccc2-c2ccc(-n3c4ccccc4c4cc(-c5ccc6c(c5)c5ccccc5n6-c5ccc(-c6ccc(-c7ccccc7)cc6)cc5)ccc43)cc21]

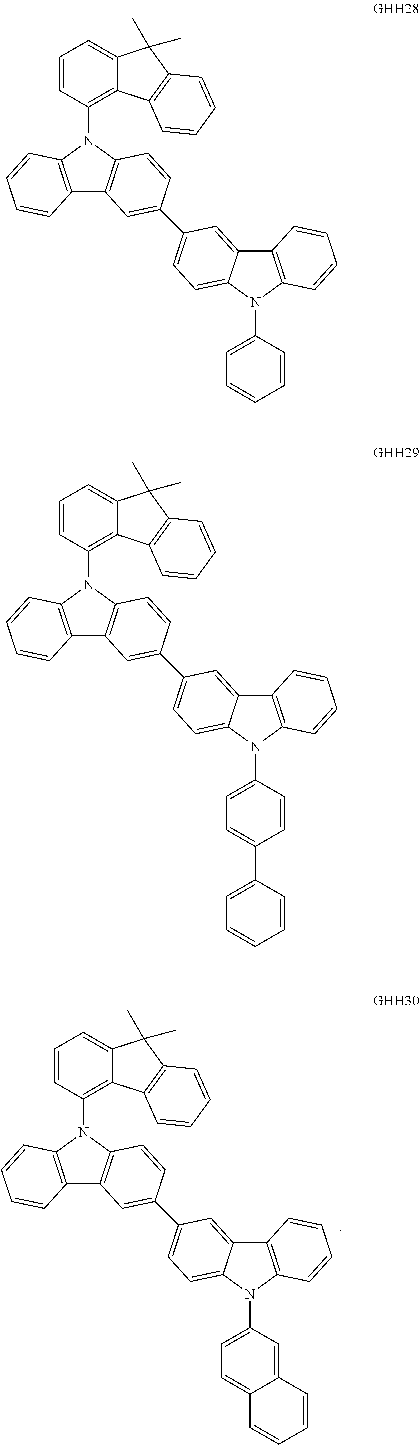 [SMILES: CC1(C)c2ccccc2-c2c(-n3c4ccccc4c4cc(-c5ccc6c(c5)c5ccccc5n6-c5ccccc5)ccc43)cccc21 ; CC1(C)c2ccccc2-c2c(-n3c4ccccc4c4cc(-c5ccc6c(c5)c5ccccc5n6-c5ccc(-c6ccccc6)cc5)ccc43)cccc21 ; CC1(C)c2ccccc2-c2c(-n3c4ccccc4c4cc(-c5ccc6c(c5)c5ccccc5n6-c5ccc6ccccc6c5)ccc43)cccc21]

14. The organic light emitting diode of claim 11, wherein the red emitting material layer further comprises a second red host selected from a compound according to Chemical Formula 3, Chemical Formula 4, Chemical Formula 5 or Chemical Formula 6: 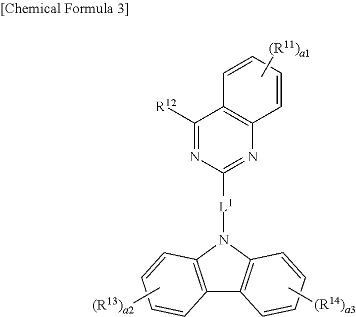
wherein, in Chemical Formula 3,
R¹¹ is an unsubstituted or substituted C₁-C₂₀ alkyl group, an unsubstituted or substituted C₆-C₃₀ aryl group or an unsubstituted or substituted C₃-C₃₀ hetero aryl group, where each R¹¹ is identical to or different from each other when a1 is 2, 3 or 4;
R¹² is hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₆-C₃₀ aryl group or an unsubstituted or substituted C₃-C₃₀ hetero aryl group, where each R¹² is identical to or different from each other when a2 is 2, 3 or 4, each R¹³ is identical to or different from each other when a3 is 2, 3 or 4, or
optionally,
two adjacent R¹³ when a2 is 2, 3 or 4, and/or
two adjacent R¹⁴ when a3 is 2, 3 or 4
can be further linked together to form an unsubstituted or substituted C₆-C₂₀ aromatic ring; and
each of a1, a2 and a3 is independently 0, 1, 2, 3 or 4, where at least one of a2 and a3 is not 0; 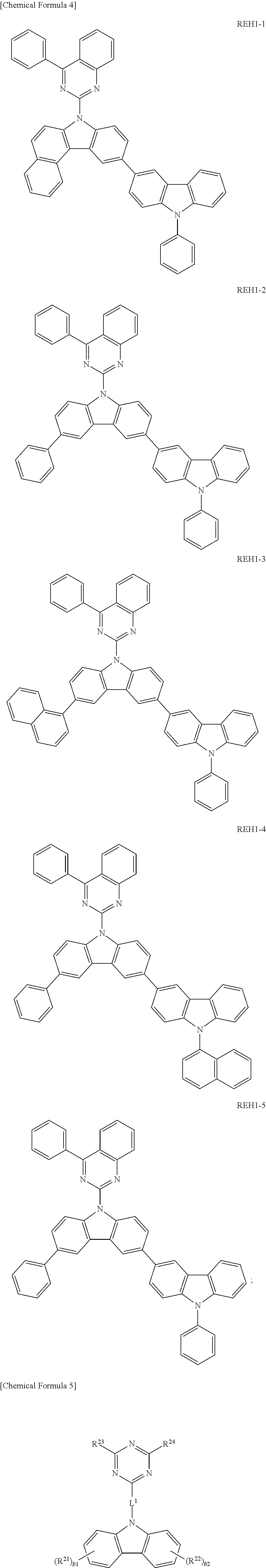
wherein, in Chemical Formula 5,
each of R²¹ and R²² is independently an unsubstituted or substituted C₁-C₂₀ alkyl group, an unsubstituted or substituted C₆-C₃₀ aryl group or an unsubstituted or substituted C₃-C₃₀ hetero aryl group, where at least one of R²¹ and R²² includes an unsubstituted or substituted carbazolyl moiety, each R²¹ is identical to or different from each other when b1 is 2, 3 or 4 and each R²² is identical to or different from each other when b2 is 2, 3 or 4;
each of R²³ and R²⁴ is independently an unsubstituted or substituted C₆-C₃₀ aryl group;
L¹ is a single bond, an unsubstituted or substituted C₆-C₃₀ arylene group or an unsubstituted or substituted C₃-C₃₀ hetero arylene group; and
each of b1 and b2 is independently 0, 1, 2, 3 or 4;

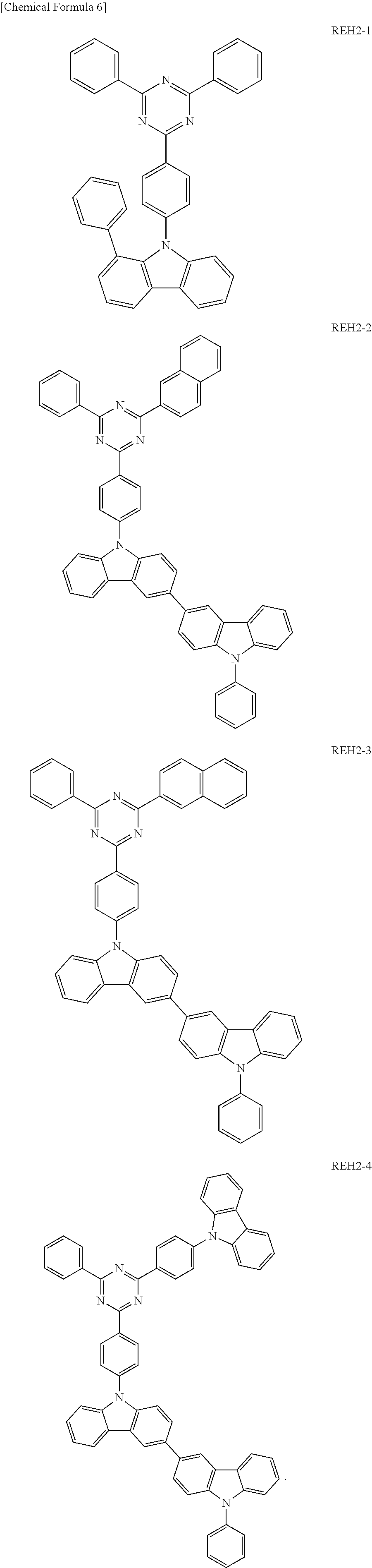

15. The organic light emitting diode of claim 11, wherein the red emitting material layer further comprises a second red host, wherein the second red host has an electron mobility larger than an electron mobility of the first red host, wherein the second red host has a lowest unoccupied molecular orbital (LUMO) energy level in a range between about −2.6 eV and about −3.2 eV, and optionally, and wherein a content of the second red host is greater than a content of the first red host in the red emitting material layer.

16. The organic light emitting diode of claim 11, wherein the green emitting material layer further comprises a second green host, wherein the second green host has an electron mobility larger than an electron mobility of the first green host, and wherein a content of the first green host is greater than a content of the second green host in the green emitting material layer.

17. The organic light emitting diode of claim 11, wherein the green emitting material layer further comprises a second green host, wherein the second green host has an electron mobility larger than an electron mobility of the first green host, and wherein the second green host has a HOMO energy level in a range between about −5.4 eV and about −5.9 eV.

18. The organic light emitting diode of claim 11, wherein the red emitting material layer further comprises a second red host, the yellow emitting material layer further comprises a second yellow-green host and the green emitting material layer further comprises a second green host,
wherein the second red host has an electron mobility larger than an electron mobility of the first red host, the second yellow-green host has an electron mobility larger than an electron mobility of the first yellow-green host and the second green host has an electron mobility larger than an electron mobility of the first green host, and
wherein the second red host has a lowest unoccupied molecular orbital (LUMO) energy level lower than a LUMO energy level of at least one of the second yellow-green host and the second green host.

19. The organic light emitting diode of claim 11, wherein the first emitting part comprises the first blue emitting material layer and the second emitting part comprises the red emitting material layer, the yellow-green emitting material layer and the green emitting material layer.

20. The organic light emitting diode of claim 11, wherein the emissive layer further comprises:
a third emitting part disposed between the second emitting part and the second electrode; and
a second charge generation layer disposed between the second emitting part and the third emitting part.

21. An organic light emitting device, comprising:
a substrate; and
the organic light emitting diode of claim 1 over the substrate.

22. An organic light emitting device, comprising:
a substrate; and
the organic light emitting diode of claim 11 over the substrate.
